(19) United States
(12) Patent Application Publication
(10) Pub. No.: US 2025/0241174 A1
(43) Pub. Date: Jul. 24, 2025

(54) DISPLAY DEVICE AND METHOD FOR MANUFACTURING THE SAME

(71) Applicant: SAMSUNG DISPLAY CO., LTD., YONGIN-SI (KR)

(72) Inventors: Seung Bin LEE, Yongin-si (KR); Kwang Sik LEE, Yongin-si (KR); Ye Ji SHIN, Yongin-si (KR); So Hyeon LEE, Yongin-si (KR); Jong Heon LEE, Yongin-si (KR)

(21) Appl. No.: 18/813,114

(22) Filed: Aug. 23, 2024

(30) Foreign Application Priority Data
Jan. 23, 2024 (KR) 10-2024-0009912

(51) Int. Cl. H10K 59/80; G09G 3/3233; H10K 59/88

(52) U.S. Cl. CPC H10K 59/873; H10K 59/88; G09G 3/3233; G09G 2300/0819; G09G 2300/0852

(57) ABSTRACT

A display device including: a substrate; a circuit layer; an element layer; and an encapsulation layer, the substrate includes: a display area; a non-display area; a hole area; and a hole peripheral area disposed between the hole area and the display area, and the circuit layer includes: an interlayer insulating layer disposed on the substrate; two or more encapsulation auxiliary portions disposed in the hole peripheral area on the interlayer insulating layer, wherein the two or more encapsulation auxiliary portions surround the hole area; and one or more concave portions disposed between the two or more encapsulation auxiliary portions, wherein the one or more concave portions are located on the interlayer insulating layer, wherein in a direction from the substrate to the interlayer insulating layer, each of the two or more encapsulation auxiliary portions has a cross-sectional shape whose width gradually narrows as it approaches the interlayer insulating layer.

### CROSS-REFERENCE TO RELATED APPLICATION

This application claims priority under 35 U.S.C. § 119 to Korean Patent Application No. 10-2024-0009912 filed on Jan. 23, 2024 in the Korean Intellectual Property Office, the disclosure of which is incorporated by reference herein in its entirety.

### 1. TECHNICAL FIELD

The present disclosure relates to a display device and a method for manufacturing the same.

### 2. DESCRIPTION OF THE RELATED ART

As society becomes increasingly information-oriented, the demand for versatile display devices continues to grow. These devices are integral to a wide range of electronic products such as smartphones, digital cameras, laptops, navigation systems, and smart televisions.

The display device may be a flat panel type such as a liquid crystal display, a field emission display or a light emitting display. Light emitting display devices may include an organic light emitting display device including organic light emitting elements, an inorganic light emitting display device including inorganic light emitting elements such as inorganic semiconductors, and a micro light emitting display device including micro light emitting elements.

The organic light emitting display device displays images using light-emitting elements, each containing a light-emitting layer made of organic material. The organic light emitting display device utilizes self-light-emitting elements, which can offer superior performance in terms of power consumption, response speed, luminous efficiency, brightness, and viewing angles compared to other types of display devices.

One side surface of the display device serves as the display surface, which includes a display area for presenting images. The display area contains emission areas that emit light in various luminances and colors.

### SUMMARY

The display device may include a light transmitting hole disposed in a hole area surrounded by the display area.

The element layer may include light emitting elements disposed in emission areas, with each light emitting element including a first common layer between an anode electrode and a light emitting layer, and a second common layer between the light emitting layer and a cathode electrode.

The cathode electrode and the second common layer are disposed entirely within the display area, and may also be disposed in the hole area surrounded by the display area and a hole peripheral area between the hole area and the display area.

Accordingly, the second common layer disposed adjacent to the light transmitting hole facilitates the permeation of oxygen or moisture, which can significantly reduce the lifespan of the display device.

In view of the above, embodiments of the present disclosure provide a display device designed to extend its lifespan by delaying the permeation of oxygen or moisture through the second common layer in the hole peripheral area, and a method for manufacturing the same.

According to an embodiment of the present disclosure there is provided a display device including: a substrate; a circuit layer disposed on the substrate; an element layer disposed on the circuit layer; and an encapsulation layer disposed on the element layer, wherein the substrate includes: a display area in which emission areas are arranged; a non-display area adjacent to the display area; a hole area surrounded by the display area; and a hole peripheral area disposed between the hole area and the display area, and the circuit layer includes: an interlayer insulating layer disposed on the substrate; two or more encapsulation auxiliary portions disposed in the hole peripheral area on the interlayer insulating layer, wherein the two or more encapsulation auxiliary portions surround the hole area; and one or more concave portions disposed between the two or more encapsulation auxiliary portions, wherein the one or more concave portions are located on the interlayer insulating layer, wherein in a direction from the substrate to the interlayer insulating layer, each of the two or more encapsulation auxiliary portions has a cross-sectional shape whose width gradually narrows as it approaches the interlayer insulating layer.

The display device further includes a light transmitting hole in the hole area, wherein the light transmitting hole penetrates the substrate, the circuit layer, the element layer, and the encapsulation layer.

The display device further includes one or more hole peripheral dams disposed between the two or more encapsulation auxiliary portions and the hole area, wherein the one or more hole peripheral dams surround the hole area, wherein the encapsulation layer includes: a first encapsulation layer disposed on the element layer; a second encapsulation layer disposed on the first encapsulation layer and overlapping the display area; and a third encapsulation layer disposed on the first encapsulation layer and the second encapsulation layer, wherein the second encapsulation layer includes an organic insulating material that extends to the one or more hole peripheral dams and is spaced from the hole area; the first encapsulation layer and the third encapsulation layer include an inorganic insulating material, and are in contact with each other in a region between the hole area and the one or more hole peripheral dams, and the two or more encapsulation auxiliary portions overlap the second encapsulation layer.

The circuit layer further includes: a first source-drain conductive layer disposed on the interlayer insulating layer; a first planarization layer disposed in the display area on the interlayer insulating layer, wherein the first planarization layer is spaced apart from the two or more encapsulation auxiliary portions, and covers the first source-drain conductive layer; a second source-drain conductive layer disposed on the first planarization layer; and a second planarization layer disposed on the first planarization layer, wherein the second planarization layer covers the second source-drain conductive layer, and each of the two or more encapsulation auxiliary portions includes: a first auxiliary layer disposed on the interlayer insulating layer and spaced apart from the first planarization layer; and a second auxiliary layer disposed on the first auxiliary layer and formed in the same layer as the second source-drain conductive layer, wherein the second auxiliary layer covers a top surface of the first auxiliary layer, extends to a side surface of the first auxiliary layer, and is spaced apart from the interlayer insulating layer.

The first auxiliary layer includes a negative photoresist material that is cured by exposure, and has a cross-sectional shape that gradually widens as it extends away from the interlayer insulating layer in the direction from the substrate to the interlayer insulating layer.

Each of the two or more encapsulation auxiliary portions is disposed on a side facing an adjacent encapsulation auxiliary portion, and further includes one or more grooves formed on a side surface of the first auxiliary layer.

The first encapsulation layer overlapping the two or more encapsulation auxiliary portions is contiguous, and the first encapsulation layer overlapping the one or more concave portions is spaced apart from the second encapsulation layer.

The element layer includes: anode electrodes disposed in the emission areas; a pixel defining layer disposed in a non-emission area between the emission areas, wherein the pixel defining layer covers an edge of each of the anode electrodes; a spacer layer disposed on the pixel defining layer; first common layers disposed on the anode electrodes; light emitting layers disposed on the first common layers; a second common layer disposed in the display area, wherein the second common layer covers the pixel defining layer, the spacer layer, and the light emitting layers; and a cathode electrode disposed on the second common layer.

The second common layer includes: two or more first split portions disposed on the second auxiliary layer of each of the two or more encapsulation auxiliary portions; and one or more second split portions disposed in the one or more concave portions, wherein the one or more second split portions are spaced apart from the two or more first split portions.

Between the two or more encapsulation auxiliary portions, the cathode electrode is in contact with the interlayer insulating layer.

In the circuit layer, each of the one or more hole peripheral dams includes two or more dam layers, and each of the two or more dam layers is disposed in the same layer as the second planarization layer, the pixel defining layer, or the spacer layer.

The display device further includes: two or more dummy auxiliary portions disposed between the one or more hole peripheral dams and the hole area, wherein the two or more dummy auxiliary portions surround the hole area; and one or more dummy concave portions disposed between the two or more dummy auxiliary portions, wherein the second common layer further includes: two or more third split portions disposed on the two or more dummy auxiliary portions; and one or more fourth split portions disposed in the one or more dummy concave portions, wherein the one or more fourth split portions are spaced apart from the two or more third split portions.

The circuit layer further includes: a buffer layer disposed on the substrate; a first gate insulating layer disposed on the buffer layer; and a second gate insulating layer disposed on the first gate insulating layer, wherein the interlayer insulating layer is disposed on the second gate insulating layer, and the light transmitting hole penetrates the third encapsulation layer, the first encapsulation layer, the cathode electrode, the second common layer, the interlayer insulating layer, the second gate insulating layer, the first gate insulating layer, the buffer layer, and the substrate.

According to an embodiment of the present disclosure there is provided a method for manufacturing a display device, the method including: providing a substrate including a display area in which emission areas are arranged; a non-display area disposed around the display area; a hole area surrounded by the display area; and a hole peripheral area disposed between the hole area and the display area; disposing a circuit layer on the substrate; disposing an element layer on the circuit layer; disposing an encapsulation layer on the element layer; and forming a light transmitting hole penetrating the substrate, the circuit layer, the element layer, and the encapsulation layer in the hole area, wherein the disposing of the circuit layer includes: disposing an interlayer insulating layer on the substrate; disposing a first source-drain conductive layer on the interlayer insulating layer; disposing a first planarization layer covering the first source-drain conductive layer in the display area on the interlayer insulating layer; disposing two or more first auxiliary layers surrounding the hole area in the hole peripheral area on the interlayer insulating layer by partially etching a negative photoresist material laminated on the interlayer insulating layer, wherein the two or more first auxiliary layers are spaced apart from the first planarization layer; disposing a second source-drain conductive layer on the first planarization layer, and disposing two or more second auxiliary layers on the two or more first auxiliary layers; and disposing a second planarization layer covering the second source-drain conductive layer on the first planarization layer.

A cross section of each of the two or more first auxiliary layers has a shape whose width gradually decreases as it approaches the interlayer insulating layer, and the disposing of the second source-drain conductive layer and the two or more second auxiliary layers includes: laminating a conductive material layer; and partially removing the conductive material layer to provide the second source-drain conductive layer as a conductive material layer on the first planarization layer, and to provide the two or more second auxiliary layers as a conductive material layer on the two or more first auxiliary layers, wherein the two or more second auxiliary layers cover top surfaces of the two or more first auxiliary layers, extend to a part of side surfaces of the two or more first auxiliary layers, and are spaced apart from the interlayer insulating layer, and in the disposing of the second source-drain conductive layer and the two or more second auxiliary layers, two or more encapsulation auxiliary portions each having a laminated structure of the first auxiliary layer and the second auxiliary layer are formed.

In the partially removing of the conductive material layer, between the two or more first auxiliary layers, a part of the interlayer insulating layer is removed together with the conductive material layer, and one or more concave portions are formed on the interlayer insulating layer.

The disposing of the element layer includes: disposing anode electrodes of the emission areas on the second planarization layer; disposing a pixel defining layer of a non-emission area disposed between the emission areas on the second planarization layer, and disposing a spacer layer on a part of the pixel defining layer; disposing first common layers on the anode electrodes; disposing light emitting layers on the first common layers; disposing a second common layer covering the pixel defining layer, the spacer layer, and the light emitting layers in the display area; and disposing a cathode electrode on the second common layer, wherein the second common layer includes: two or more first split portions disposed on the two or more second auxiliary layers; and one or more second split portions disposed in the one or more concave portions and spaced apart from the two or more first split portions.

The disposing of the circuit layer further includes: after disposing the second source-drain conductive layer and the two or more second auxiliary layers, performing an ashing process on the side surfaces of the two or more first auxiliary layers to form one or more grooves in each of the two or more first auxiliary layers, and the one or more grooves of each of the two or more first auxiliary layers are disposed on a side facing an adjacent first auxiliary layer, and are formed on a side surface of the first auxiliary layer.

In the disposing of the pixel defining layer and the spacer layer, one or more hole peripheral dams disposed between the two or more encapsulation auxiliary portions and the hole area and surrounding the hole area are formed, the one or more hole peripheral dams include two or more dam layers, each of the two or more dam layers is formed in the same layer as one of the second planarization layer, the pixel defining layer, and the spacer layer, and the disposing of the encapsulation layer includes: disposing a first encapsulation layer covering the cathode electrode and containing an inorganic insulating material; disposing a second encapsulation layer overlapping the display area on the first encapsulation layer; and laminating an inorganic insulating material on the first encapsulation layer and disposing a third encapsulation layer covering the second encapsulation layer, wherein the second encapsulation layer includes an organic insulating material extending to the one or more hole peripheral dams, overlapping the two or more encapsulation auxiliary portions, and spaced away from the hole area.

Some of the first encapsulation layer overlapping the two or more second auxiliary layers are connected to each other.

A display device according to embodiments includes a substrate, a circuit layer disposed on the substrate, an element layer disposed on the circuit layer, and an encapsulation layer disposed on the element layer.

The substrate includes a display area where emission areas are arranged, a non-display area disposed around the display area, a hole area surrounded by the display area, and a hole peripheral area disposed between the hole area and the display area.

The circuit layer includes an interlayer insulating layer disposed on the substrate, two or more encapsulation auxiliary portions disposed in the hole peripheral area on the interlayer insulating layer and sequentially surrounding the hole area, and one or more concave portions disposed between the two or more encapsulation auxiliary portions and engraved on the interlayer insulating layer.

In accordance with embodiments, each of the two or more encapsulation auxiliary portions may include a first auxiliary layer disposed on the interlayer insulating layer, and a second auxiliary layer disposed on the first auxiliary layer.

The first auxiliary layer includes a negative photoresist material which is cured by exposure, and thus may have a cross-sectional shape whose width gradually increases as it becomes more distant from the interlayer insulating layer in a direction between the substrate and the interlayer insulating layer.

The second auxiliary layer may cover the top surface of the first auxiliary layer, extend to a part of the side surface of the first auxiliary layer, and be spaced apart from the interlayer insulating layer.

Accordingly, each of the two or more encapsulation auxiliary portions may have a cross-sectional shape whose width gradually decreases as it approaches the interlayer insulating layer in the direction from the substrate to the interlayer insulating layer. In other words, the cross section of each side surface of the two or more encapsulation auxiliary portions may have a reverse tapered shape.

Therefore, the second common layer may include first split portions disposed on the two or more encapsulation auxiliary portions, and a second split portion disposed on the interlayer insulating layer between the two or more encapsulation auxiliary portions and spaced apart from the first split portions. In other words, the second common layer may be separated by the two or more encapsulation auxiliary portions. Accordingly, the generation of an oxygen or moisture permeation path through the second common layer may be delayed.

Further, in accordance with embodiments, the separation distance between the side surfaces of the two or more encapsulation auxiliary portions and the interlayer insulating layer may increase due to the one or more concave portions disposed between the two or more encapsulation auxiliary portions and engraved on the interlayer insulating layer. Therefore, the separation distance between the first split portions and the second split portion increases, further delaying the formation of the oxygen or moisture permeation path through the second common layer.

Therefore, according to embodiments, the lifespan of the display device can be improved.

In addition, in accordance with embodiments, the first auxiliary layer of the two or more encapsulation auxiliary portions includes a negative photoresist material. This allows it to be relatively easily formed with a reverse tapered cross section due to differences in exposure amounts for each thickness.

Therefore, even if the encapsulation auxiliary portions are included to separate the second common layer, the method for manufacturing a display device can remain uncomplicated.

### BRIEF DESCRIPTION OF THE DRAWINGS

The above and other features of the present disclosure will become more apparent by describing in detail embodiments thereof with reference to the attached drawings, in which:

FIG. 1 is a perspective view illustrating a display device according to embodiments;

FIG. 2 is a plan view illustrating the display device of FIG. 1;

FIG. 3 is a cross-sectional view taken along line A-A′ of FIG. 2;

FIG. 4 is a layout diagram illustrating part B of FIG. 2;

FIG. 5 is an equivalent circuit diagram showing the light emitting pixel driver of FIG. 4;

FIG. 6 is a cross-sectional view showing the light emitting element and the first and sixth transistors of FIG. 5;

FIG. 7 is a layout diagram illustrating part C of FIG. 2;

FIGS. 8, 9, and 10 are cross-sectional views taken along line D-D′ of FIG. 7 according to embodiments;

FIGS. 11, 12, and 13 are flowcharts illustrating a method for manufacturing the display device according to embodiments; and

FIGS. 14, 15, 16, 17, 18, 19, 20, 21, 22, 23 and 24 are process views showing some steps among the steps of FIGS. 11, 12 and 13.

### DETAILED DESCRIPTION OF THE EMBODIMENTS

The features and methods of the present disclosure can be better understood by referring to the following detailed description of the embodiments and the accompanying drawings. The present disclosure may, however, be embodied in many different forms and should not be limited to the embodiments set forth herein.

It will be understood that when an element or layer is referred to as being “on” another element or layer, the element or layer can be directly on another element or layer or intervening elements or layers between them. Like reference numerals refer to like elements throughout the specification. The shapes, sizes, ratios, angles, numbers, etc., depicted in the drawings are merely examples, and the present disclosure is not limited to the illustrated details.

Terms such as first, second, third, etc., may be used herein for distinguishing various elements and should not impose any limitations. These terms are used to distinguish one element from another element. Thus, a first element discussed below could be termed a second element.

Features of various embodiments of the present disclosure may be partially or entirely coupled, combined, and inter-operated in different technical ways. These embodiments may be implemented independently or together in a co-dependent relationship.

Hereinafter, specific embodiments will be described with reference to the accompanying drawings.

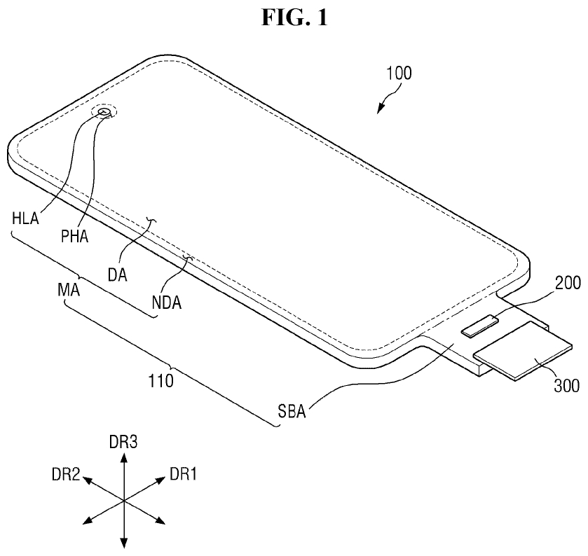

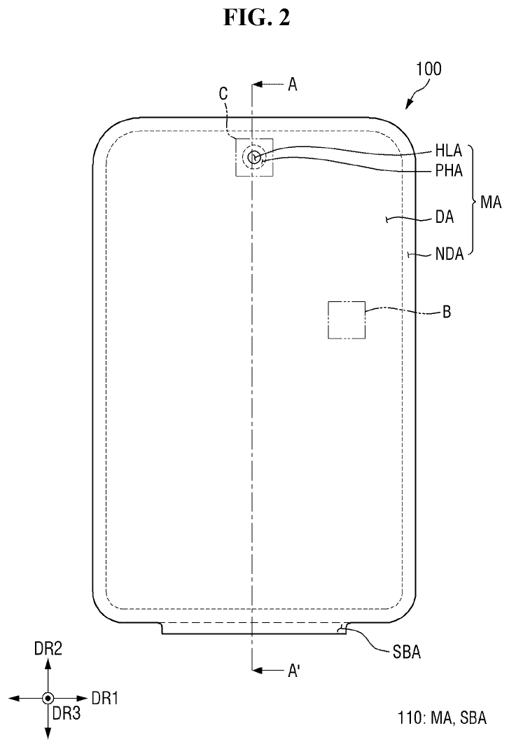

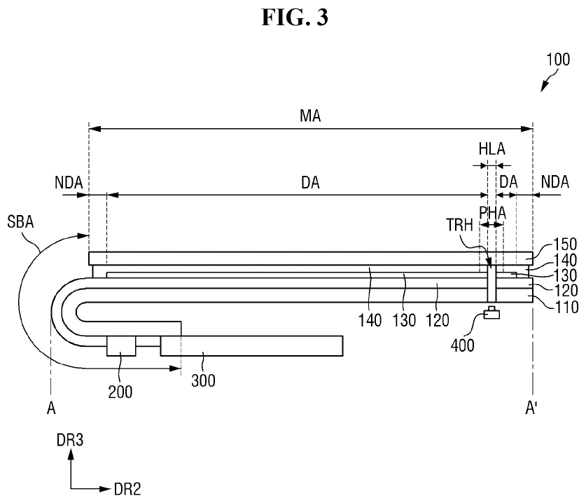

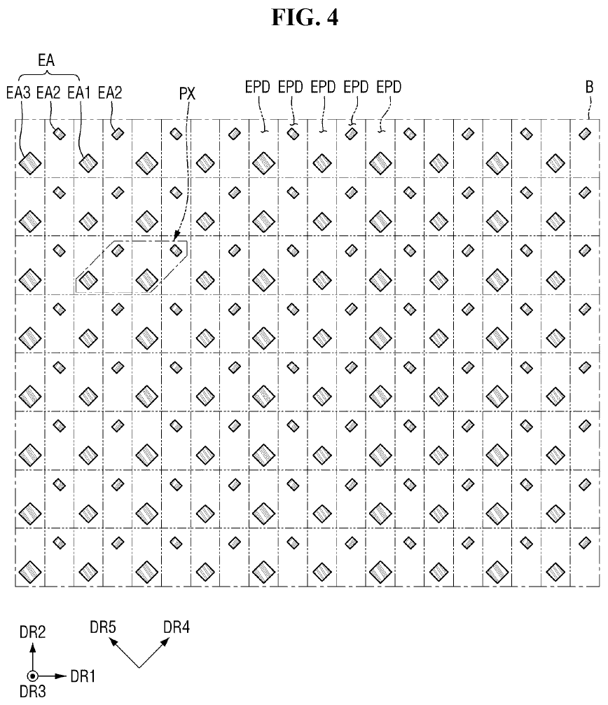

FIG. 1 is a perspective view illustrating a display device according to embodiments. FIG. 2 is a plan view illustrating the display device of FIG. 1. FIG. 3 is a cross-sectional view taken along line A-A′ of FIG. 2. FIG. 4 is a layout diagram illustrating part B of FIG. 2.

Referring to FIGS. 1 and 2, a display device 100 is a device for displaying a moving image or a still image. The display device 100 may be used as a display screen of various devices, such as a television, a laptop, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation system and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may also be applied to a display device including an organic insulating material, an organic light emitting material, and a metal material.

The display device 100 may be designed to be flat, but it is not limited to this form. For example, the display device 100 may include curved portions formed at left and right ends with either a constant or varying curvature. In addition, the display device 100 may be made flexible, allowing it to be curved, bent, folded, or rolled.

As illustrated in FIGS. 1, 2 and 3, the display device 100 includes a substrate 110.

The substrate 110 may include a main region MA corresponding to a display surface of the display device 100 and a sub-region SBA protruding from one side of the main region MA.

As shown in FIG. 2, the main region MA may include a display area DA located primarily at the center, and a non-display area NDA disposed around the display area DA.

The display area DA may, in a plan view, be formed in a rectangular shape having short sides extending in a first direction DR1 and long sides extending in a second direction DR2 intersecting the first direction DR1. The corner where the short side in the first direction DR1 and the long side in the second direction DR2 meet may be rounded with a predetermined curvature or may form a right-angle. The planar shape of the display area DA is not limited to the rectangular shape, and may instead be formed in another polygonal shape, a circular shape or an elliptical shape.

The non-display area NDA may be disposed at the edge of the main region MA to surround the display area DA.

The sub-region SBA may be a region protruding from the non-display area NDA of the main region MA to one side in the second direction DR2.

FIGS. 2 and 3 illustrate the display device 100 with a part of the sub-region SBA in a bent state.

As shown in FIGS. 2 and 3, a part of the sub-region SBA is curved, allowing another part of the sub-region SBA to be disposed on the rear surface of the substrate 110 opposite to the display surface.

A display driving circuit 200 may be mounted on the sub-region SBA of the substrate 110, and a circuit board 300 may be attached thereto.

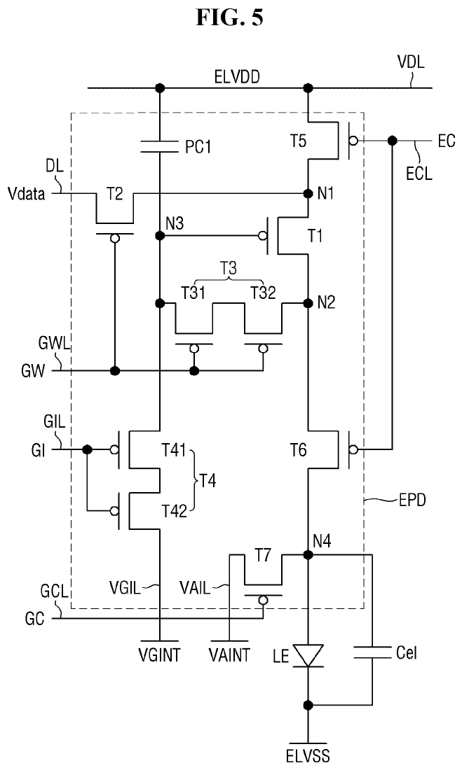

The display driving circuit 200 may be electrically connected to the data lines DL (see FIG. 5) of the circuit layer 120 (see FIG. 3). The display driving circuit 200 may output a data signal Vdata (see FIG. 5) based on control signals and power voltages supplied from the circuit board 300.

The display driving circuit 200 may be provided as an integrated circuit (IC) and mounted on the sub-region SBA of the substrate 110 by a chip on glass (COG) method, a chip on plastic (COP) method, or an ultrasonic method. However, this is only an example, and one embodiment is not limited thereto. For example, the display driving circuit 200 may be mounted on the circuit board 300.

One end of the circuit board 300 may be attached onto pads disposed on one edge of the sub-region SBA of the substrate 110 by using an anisotropic conductive film.

The circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

The substrate 110 according to embodiments, may include a hole area HLA surrounded by the display area DA, and a hole peripheral area PHA disposed between the hole area HLA and the display area DA.

Referring to FIG. 3, the display device 100 according to embodiments includes the substrate 110, a circuit layer 120 disposed on the substrate 110, an element layer 130 disposed on the circuit layer 120, and an encapsulation layer 140 disposed on the element layer 130.

The display device 100 according to embodiments may further include a cover window 150 disposed on the encapsulation layer 140. The cover window 150 may be bonded to face the substrate 110. Alternatively, the cover window 150 may be coupled to a bracket under the rear surface of the substrate 110. The bracket may accommodate the substrate 110, the display driving circuit 200 and the circuit board 300.

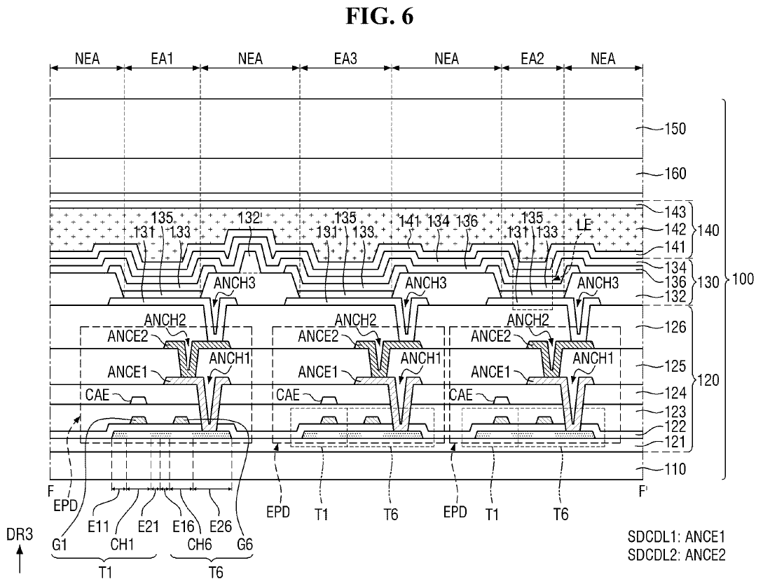

The display device 100 according to embodiments may further include a touch sensor layer 160 (see FIG. 6) disposed on the encapsulation layer 140.

The display device 100 according to embodiments may further include a polarization layer disposed on the encapsulation layer 140 to reduce the reflection of external light.

The substrate 110 may be formed of an insulating material such as a polymer resin. For example, the substrate 110 may be formed of polyimide. The substrate 110 may be a flexible substrate which can be bent, folded or rolled.

Alternatively, the substrate 110 may be formed of an insulating material such as glass or the like.

The substrate 110 may include the main region MA and the sub-region SBA. The main region MA may include the display area DA and the non-display area NDA.

The circuit layer 120 may include conductive layers, one or more semiconductor layers, and insulating layers interposed therebetween. The circuit layer 120 may include transistors formed of one or more semiconductor layers and one or more conductive layers, and signal lines each being formed of at least one of the conductive layers.

The element layer 130 may include light emitting elements that emit light in response to the driving current applied by the circuit layer 120.

The encapsulation layer 140 may cover both the circuit layer 120 and the element layer 130, preventing the permeation of oxygen or moisture into the element layer 130.

The cover window 150 may include a light transmitting material. The cover window 150 may be made of an inorganic material such as glass, or an organic material such as plastic or a polymer material.

The display device 100 according to embodiments, may further include a light transmitting hole TRH which overlaps with the hole area HLA and penetrates the circuit layer 120, the element layer 130 and the encapsulation layer 140, an optical device 400 which is disposed below the substrate 110 and overlaps with the light transmitting hole TRH. The optical device 400 may process light incident through the light transmitting hole TRH.

Referring to FIG. 4, the display area DA of the substrate 110 of the display device 100 according to embodiments may include emission areas EA. In addition, the display area DA may further include a non-emission area disposed in a gap between the emission areas EA.

The element layer 130 (see FIG. 3) may include light emitting elements LE (see FIG. 5) respectively disposed in the emission areas EA.

The circuit layer 120 (see FIG. 3) may include light emitting pixel drivers EPD arranged side by side in the first direction DR1 and the second direction DR2 in the main region MA. The light emitting pixel drivers EPD may be electrically connected to the light emitting elements LE (see FIG. 5) of the element layer 130.

The emission areas EA may have a rhombus shape or a rectangular shape in a plan view. However, this is only an example, and the planar shape of the emission areas EA according to one embodiment is not limited to that illustrated in FIG. 4. For example, in a plan view, the emission areas EA may have a polygonal shape such as a square, a pentagon, a hexagon, etc., or may have a circular or elliptical shape, including curved edges.

The emission areas EA may include first emission areas EA1 that emit light of a first color in a predetermined wavelength band, second emission areas EA2 that emit light of a second color in a wavelength band lower than that of the first color, and third emission areas EA3 that emit light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be formed by the first emission area EA1, the second emission area EA2, and the third emission area EA3 adjacent to each other within the emission areas EA.

In other words, the pixels PX may serve as a basic unit for displaying various colors including white at a predetermined luminance.

Each of the pixels PX may include at least one first emission area EA1, at least one second emission area EA2, and at least one third emission area EA3 that are adjacent to each other. Accordingly, each of the pixels PX may display various colors by mixing the light emitted from the adjacent first emission area EA1, second emission area EA2, and third emission area EA3.

FIG. 5 is an equivalent circuit diagram showing the light emitting pixel driver of FIG. 4.

Referring to FIG. 5, one of the light emitting elements LE of the element layer 130 may be electrically connected between one of the light emitting pixel drivers EPD of the circuit layer 120 and a second power ELVSS.

For example, the anode electrode of the light emitting element LE is electrically connected to the light emitting pixel driver EPD, and the cathode electrode of the light emitting element LE may be applied with the second power ELVSS lower than a first power ELVDD.

A capacitor Cel connected in parallel with the light emitting element LE refers to a parasitic capacitance between the anode electrode and the cathode electrode of the light emitting element LE.

The circuit layer 120 may further include a first power line VDL for transmitting the first power ELVDD, a first initialization voltage line VGIL for transmitting a first initialization voltage VGINT, and a second initialization voltage line VAIL for transmitting a second initialization voltage VAINT.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a scan initialization line GIL for transmitting a scan initialization signal GI.

One light emitting pixel driver EPD of the circuit layer 120 may include a first transistor T1 configured to generate a driving current for driving the light emitting element LE, two or more transistors T2 to T7 electrically connected to the first transistor T1 or the light emitting element LE, and at least one capacitor PC1.

The first transistor T1 may be electrically connected between a first node N1 and a second node N2.

A first electrode (e.g., the source electrode) of the first transistor T1 may be electrically connected to the first node N1, and electrically connected to the first power line VDL through the fifth transistor T5.

A second electrode (e.g., the drain electrode) of the first transistor T1 may be electrically connected to the second node N2, and electrically connected to the anode electrode of the light emitting element LE through the sixth transistor T6.

The second transistor T2 may be electrically connected between a data line DL and the first node N1.

In other words, the first electrode of the first transistor T1 may be electrically connected to the data line DL through the second transistor T2.

The second transistor T2 may be turned on by the scan write signal GW of the scan write line GWL.

A gate electrode of the first transistor T1 may be electrically connected to a third node N3.

The capacitor PC1 may be electrically connected between the third node N3 and the first power line VDL.

Accordingly, the potential of the gate electrode of the first transistor T1 may be maintained at the voltage charged in the first power line VDL.

Further, when the data signal Vdata of the data line DL is transmitted to the first electrode of the first transistor T1 through the turned-on second transistor T2, the voltage difference between the gate electrode of the first transistor T1 and the first electrode of the first transistor T1 may be the difference between the first power ELVDD and a data signal Vdata.

In this case, when the voltage difference between the gate electrode of the first transistor T1 and the first electrode of the first transistor T1, e.g., the gate-source voltage difference, becomes equal to or greater than a threshold voltage, the first transistor T1 may turn on, thereby generating a drain-source current corresponding to the data signal Vdata.

Then, when the fifth transistor T5 and the sixth transistor T6 are turned on, the first transistor T1 may be connected in series with the light emitting element LE between the first power ELVDD and the second power ELVSS. Accordingly, the drain-source current of the first transistor T1, corresponding to the data signal Vdata, may be supplied as the driving current for the light emitting element LE.

Accordingly, the light emitting element LE may emit light with a luminance corresponding to the data signal Vdata.

The third transistor T3 may be electrically connected between the second node N2 and the third node N3. In other words, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

A first electrode of the first sub-transistor T31 may be connected to the gate electrode of the first transistor T1, a second electrode of the first sub-transistor T31 may be connected to a first electrode of the second sub-transistor T32, and a second electrode of the second sub-transistor T32 may be connected to the second electrode of the first transistor T1.

In this way, it is possible to prevent the potential of the gate electrode of the first transistor T1 from changing due to leakage current caused by the third transistor T3 when it is not turned on.

The first sub-transistor T31 and the second sub-transistor T32 may be turned on by the scan write signal GW of the scan write line GWL.

When the first sub-transistor T31 and the second sub-transistor T32 are turned on, the voltage difference between the second node N2 and the third node N3 may be initialized.

The fourth transistor T4 may be electrically connected between the third node N3 and the first initialization voltage line VGIL. In other words, the fourth transistor T4 may be connected between the gate electrode of the first transistor Tl and the first initialization voltage line VGIL.

The fourth transistor T4 may include a plurality of sub-transistors connected in series. For example, the fourth transistor T4 may include a third sub-transistor T41 and a fourth sub-transistor T42.

A first electrode of the third sub-transistor T41 may be connected to the gate electrode of the first transistor T1, a second electrode of the third sub-transistor T41 may be connected to a first electrode of the fourth sub-transistor T42, and a second electrode of the fourth sub-transistor T42 may be connected to the first initialization voltage line VGIL.

In this way, it is possible to prevent the potential of the gate electrode of the first transistor T1 from changing due to leakage current caused by the fourth transistor T4 when it is not turned on.

The third sub-transistor T41 and the fourth sub-transistor T42 may be turned on by a scan initialization signal GI of a scan initialization line GIL.

When the third sub-transistor T41 and the fourth sub-transistor T42 are turned on, the potential of the third node N3 may be initialized to the first initialization voltage VGINT.

The fifth transistor T5 may be electrically connected between the first node N1 and the first power line VDL.

The sixth transistor T6 may be electrically connected between the second node N2 and a fourth node N4.

The fourth node N4 may be electrically connected to the anode electrode of the light emitting element LE.

The fifth transistor T5 and the sixth transistor T6 may be turned on by the emission control signal EC of the emission control line ECL.

The seventh transistor T7 may be electrically connected between the fourth node N4 and the second initialization voltage line VAIL.

The seventh transistor T7 may be turned on by the gate control signal GC of the gate control line GCL.

Through the turned-on seventh transistor T7, the potential of the fourth node N4 may be initialized to the second initialization voltage VAINT.

According to embodiments, the first to seventh transistors T1 to T7 may be P-type MOSFETs. Alternatively, among the first to seventh transistors T1 to T7, the third transistor T3 and the fourth transistor T4 may be N-type MOSFETs instead of P-type MOSFETs.

FIG. 6 is a cross-sectional view showing the light emitting element and the first and sixth transistors of FIG. 5.

Referring to FIG. 6, the display device 100 according to embodiments may include the substrate 110, the circuit layer 120 on the substrate 110, the element layer 130 on the circuit layer 120, and the encapsulation layer 140 on the element layer 130.

The display device 100 according to embodiments may further include the touch sensor layer 160 on the encapsulation layer 140, and the cover window 150 on the touch sensor layer 160. The display device 100 may further include a polarization layer disposed between the touch sensor layer 160 and the cover window 150.

In accordance with embodiments, the circuit layer 120 may include an interlayer insulating layer 124 disposed on the substrate 110, a first source-drain conductive layer SDCDL1 (e.g., first anode connection electrode ANCE1) disposed on the interlayer insulating layer 124, a first planarization layer 125 covering the first source-drain conductive layer SDCDL1, a second source-drain conductive layer SDCDL2 (e.g., second anode connection electrode ANCE2) disposed on the first planarization layer 125, and a second planarization layer 126 covering the second source-drain conductive layer SDCDL2.

In addition, the circuit layer 120 may further include a semiconductor layer CH1, E11, E21, CH6, E16, and E26 disposed on the substrate 110, a first gate insulating layer 122 covering the semiconductor layer, a first gate conductive layer (e.g., a gate electrode G1 of the first transistor T1 and a gate electrode G6 of the sixth transistor T6) disposed on the first gate insulating layer 122, a second gate insulating layer 123 covering the first gate conductive layer, and a second gate conductive layer (e.g., a capacitor electrode CAE) disposed on the second gate insulating layer 123.

The interlayer insulating layer 124 may be disposed on the second gate insulating layer 123 and cover the second gate conductive layer.

The circuit layer 120 may further include the buffer layer 121 covering the substrate 110.

In this case, the semiconductor layer CH1, E11, E21, CH6, E16, and E26 may be disposed on the buffer layer 121.

In accordance with embodiments, each of the light emitting pixel drivers EPD may include the first transistor T1, and at least one capacitor PC1 (see FIG. 5) and the second to seventh transistors T2 to T7 (see FIG. 5) electrically connected to the first transistor T1 or the light emitting element LE (see FIG. 5).

FIG. 6 shows the first transistor T1, the sixth transistor T6, and the light emitting element LE of the light emitting pixel driver EPD of FIG. 5.

The semiconductor layer on the buffer layer 121 may include channel portions CH1 and CH6, first electrode portions E11 and E16, and second electrode portions E21 and E26 of each of the first transistor T1 and sixth transistor T6.

In each of the first transistor T1 and the sixth transistor T6, the first electrode portions E11 and E16 may be connected to one end of the channel portions CH1 and CH6, respectively, while the second electrode portions E21 and E26 may be connected to the other end of the channel portions CH1 and CH6, respectively.

The second electrode portion E21 of the first transistor T1 may be connected to the first electrode portion E16 of the sixth transistor T6.

The first gate conductive layer on the first gate insulating layer 122 may include the gate electrodes G1 and G6 of each of the first transistor T1 and sixth transistor T6.

In the first transistor T1 and the sixth transistor T6, the gate electrodes G1 and G6 may overlap the channel portions CH1 and CH6, respectively.

In the light emitting pixel driver EPD, the second transistor T2 (see FIG. 5), the first sub-transistor T31 (see FIG. 5), the second sub-transistor T32 (see FIG. 5), the third sub-transistor T41 (see FIG. 5), the fourth sub-transistor T42 (see FIG. 5), the fifth transistor T5 (see FIG. 5), and the seventh transistor T7 (see FIG. 5) are provided as the same P-type MOSFETs as the first transistor T1 and the sixth transistor T6. Therefore, redundant descriptions will be omitted below.

The second gate conductive layer on the second gate insulating layer 123 may include the capacitor electrode CAE.

The capacitor electrode CAE may overlap the gate electrode G1 of the first transistor T1.

Accordingly, the first capacitor PC1 (see FIG. 5) may be formed by the overlapping area between the capacitor electrode CAE and the gate electrode G1 of the first transistor T1.

The first source-drain conductive layer on the interlayer insulating layer 124 may include the first anode connection electrode ANCE1.

The first anode connection electrode ANCE1 may be electrically connected to the second electrode portion E26 of the sixth transistor T6 through a first anode connection hole ANCH1.

The second source-drain conductive layer on the first planarization layer 128 may include the second anode connection electrode ANCE2.

The second anode connection electrode ANCE2 may be electrically connected to the first anode connection electrode ANCE1 through a second anode connection hole ANCH2.

An anode electrode 131 of the element layer 130 may be disposed on the second planarization layer 126, and may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

The element layer 130 on the circuit layer 120 may include the light emitting elements LE respectively disposed in the emission areas EA1, EA2, and EA3.

Each of the light emitting elements LE may include a structure in which a light emitting layer 133 is disposed between the anode electrode 131 and a cathode electrode 134, which face each other.

In accordance with embodiments, the element layer 130 may include the anode electrodes 131 respectively disposed in the emission areas EA, a pixel defining layer 132 disposed in a non-emission area NEA and covering the edge of the anode electrode 131, a spacer layer 132′ disposed on a part of the pixel defining layer 132, light emitting layers 133 respectively disposed on the anode electrodes 131, and a cathode electrode 134 disposed on the light emitting layers 133, the pixel defining layer 132, and the spacer layer 132′.

Further, each of the light emitting elements LE may further include first common layers 135 disposed between the anode electrodes 131 and the light emitting layers 133, and a second common layer 136 disposed between the light emitting layers 133 and the cathode electrode 134.

The encapsulation layer 140 may be disposed on the circuit layer 120 and cover the clement layer 130.

The encapsulation layer 140 is designed to prevent the permeation of oxygen or moisture into the element layer 130 and to reduce electrical or physical impact on both the circuit layer 120 and the element layer 130.

The encapsulation layer 140 may include a first encapsulation layer 141 disposed on the circuit layer 120, covering the element layer 130, and including an inorganic insulating material, a second encapsulation layer 142 disposed on the first encapsulation layer 141, overlapping the element layer 130 of the display area DA, and including an organic insulating material, and a third encapsulation layer 143 disposed on the first encapsulation layer 141, covering the second encapsulation layer 142, and including an inorganic insulating material.

The touch sensor layer 160 may be disposed on the encapsulation layer 140. The touch sensor layer 160 may include touch electrodes that detect signals varying with the touch of a person or an object, and sense a point in the main region MA where the touch has occurred.

The cover window 150 may be disposed on the touch sensor layer 160.

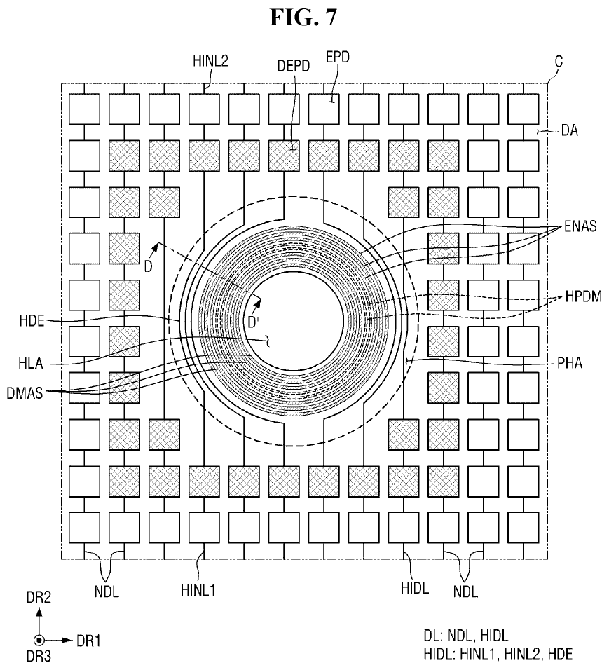

FIG. 7 is a layout diagram illustrating part C of FIG. 2.

Referring to FIG. 7, the substrate 110 (see FIG. 3) of the display device 100 according to embodiments may include a hole area HLA surrounded by the display area DA, and a hole peripheral area PHA disposed between the hole area HLA and the display area DA.

A light transmitting hole TRH (see FIG. 3) penetrating the substrate 110 (see FIG. 3), the circuit layer 120 (see FIG. 3), the element layer 130 (see FIG. 3), and the encapsulation layer 140 (see FIG. 3) may be disposed in the hole area HLA.

In accordance with embodiments, the circuit layer 120 (see FIG. 3) may further include two or more encapsulation auxiliary portions ENAS disposed in the hole peripheral area PHA and sequentially surrounding the hole area HLA.

The two or more encapsulation auxiliary portions ENAS are used for separating the second common layer 136 (see FIG. 6) of the element layer 130 (see FIG. 6) disposed in the hole peripheral area PHA. Accordingly, the permeation of oxygen or moisture through the second common layer 136 (see FIG. 6) adjacent to the light transmitting hole TRH (see FIG. 3) of the hole area HLA may be delayed.

The display device 100 according to embodiments may further include one or more hole peripheral dams HPDM disposed between the hole area HLA and the two or more encapsulation auxiliary portions ENAS in the hole peripheral area PHA. The one or more hole peripheral dams may surround the hole area HLA.

The circuit layer 120 of the display device 100 according to embodiments may further include two or more dummy auxiliary portions DMAS disposed between the hole area HLA and the one or more hole peripheral dams HPDM in the hole peripheral area PHA. The two or more dummy auxiliary portions DMAS may surround the hole area HLA.

In accordance with embodiments, the circuit layer 120 (see FIG. 3) may include the light emitting pixel drivers EPD arranged in the first direction DR1 and the second direction DR2 in the display area DA, and the data lines DL extending in the second direction DR2 and transmitting the data signal Vdata (see FIG. 5) to the light emitting pixel drivers EPD.

Since the light emitting pixel drivers EPD are arranged on both sides of the hole peripheral area PHA in the second direction DR2, the data lines DL may include hole intersection data lines HIDL intersecting the hole area HLA or the hole peripheral area PHA.

In other words, the data lines DL may include the hole intersection data lines HIDL that intersect the hole area HLA or the hole peripheral area PHA, as well as normal data lines NDL, which are the remaining data lines excluding the hole intersection data lines HIDL.

Each of the hole intersection data lines HIDL may include a first hole isolation line HINL1 facing one side in the second direction DR2 of the hole peripheral area PHA, a second hole isolation line HINL2 facing the other side in the second direction DR2 of the hole peripheral area PHA, and a hole bypass line HDE disposed in the hole peripheral area PHA and electrically connecting the first hole isolation line HINL1 and the second hole isolation line HINL2.

The hole bypass line HDE may be an arc-shaped curved line disposed between the two or more encapsulation auxiliary portions ENAS and the display area DA, extending around the two or more encapsulation auxiliary portions ENAS.

Each of the normal data lines NDL may not intersect the hole area HLA and the hole peripheral area PHA, and may not include the hole bypass line HDE.

In accordance with embodiments, the circuit layer 120 may further include dummy light emitting pixel drivers DEPD positioned closest to the hole peripheral area PHA.

The dummy light emitting pixel drivers DEPD may have the same structure as the light emitting pixel drivers EPD except that they are not electrically connected to the light emitting elements LE (see FIG. 5) of the element layer 130 (see FIG. 3).

In the process of formed the light transmitting hole TRH (see FIG. 3) in the hole area HLA, physical or chemical impact may be buffered by the dummy light emitting pixel drivers DEPD. This reduces the possibility of damage to the light emitting pixel drivers EPD in the formation process.

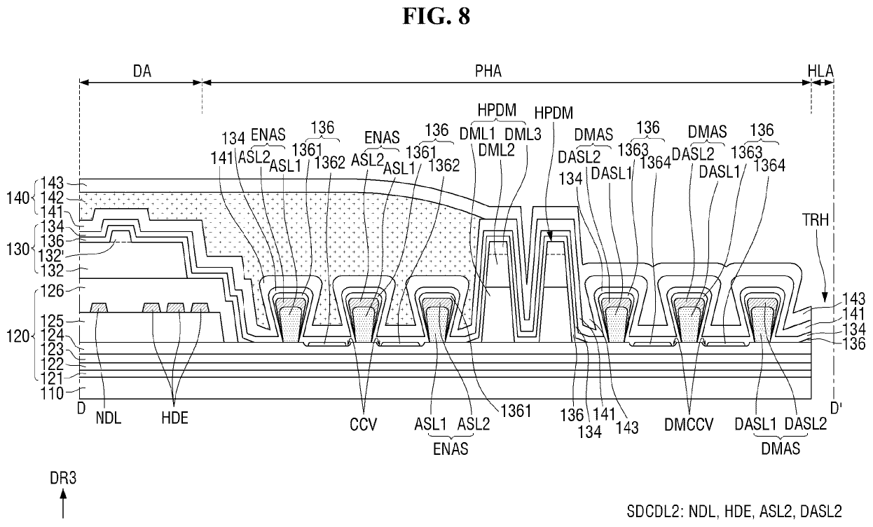

FIGS. 8, 9, and 10 are cross-sectional views taken along line D-D′ of FIG. 7 according to embodiments.

Referring to FIG. 8, the circuit layer 120 of the display device 100 according to embodiments may include the interlayer insulating layer 124 disposed on the substrate 110, the two or more encapsulation auxiliary portions ENAS disposed in the hole peripheral area PHA on the interlayer insulating layer 124, and one or more concave portions CCV disposed between the two or more encapsulation auxiliary portions ENAS and engraved on the interlayer insulating layer 124.

In accordance with embodiments, the circuit layer 120 may include a first source-drain conductive layer SDCDL1 (see FIG. 6) disposed on the interlayer insulating layer 124, a first planarization layer 125 disposed in the display area DA on the interlayer insulating layer 124, spaced apart from the two or more encapsulation auxiliary portions ENAS, and covering the first source-drain conductive layer SDCDL1 (see FIG. 6), a second source-drain conductive layer SDCDL2 disposed on the first planarization layer 125, and a second planarization layer 126 disposed on the first planarization layer 125 and covering the second source-drain conductive layer SDCDL2.

The second source-drain conductive layer SDCDL2 may include the data lines DL (sec FIG. 7).

The data lines DL (see FIG. 7) may include the hole intersection data lines HIDL (see FIG. 7) and the normal data lines NDL. The hole intersection data line HIDL (see FIG. 7) may include the first hole isolation line HINL1 (see FIG. 7), the second hole isolation line HINL2 (see FIG. 7), and the hole bypass line HDE.

In other words, the second source-drain conductive layer SDCDL2 may include the normal data lines NDL and the hole bypass line HDE.

As shown in FIG. 6, in accordance with embodiments, the element layer 130 may include the anode electrodes 131 disposed in the emission areas EA (see FIG. 4), the pixel defining layer 132 disposed in the non-emission area NEA between the emission areas EA (see FIG. 4) and covering the edges of the anode electrodes 131, the spacer layer 132′ disposed on a part of the pixel defining layer 132, the first common layers 135 disposed on the anode electrodes 131, the light emitting layers 133 disposed on the first common layers 135, the second common layer 136 covering the pixel defining layer 132, the spacer layer 132′, and the light emitting layers 133, and the cathode electrode 134 disposed on the second common layer 136.

The anode electrode 131 and the pixel defining layer 132 may be disposed on the second planarization layer 126 of the circuit layer 120.

The spacer layer 132′ may protrude in a third direction DR3 from some parts of the pixel defining layer 132.

As shown in FIG. 7, in accordance with embodiments, the display device 100 may include the one or more hole peripheral dams HPDM disposed between the two or more encapsulation auxiliary portions ENAS and the hole area HLA. The one or more hole peripheral dams HPDM may surround the hole area HLA. In other words, the one or more hole peripheral dams HPDM may be sequentially arranged between the two or more encapsulation auxiliary portions ENAS and the hole area HLA.

As shown in FIG. 8, each of the one or more hole peripheral dams HPDM may include two or more dam layers DML1, DML2, and DML3.

Each of the two or more dam layers DML1, DML2, and DML3 may be disposed in the same layer as one of the second planarization layer 126, the pixel defining layer 132, and the spacer layer 132′.

For example, each of the one or more hole peripheral dams HPDM may include the first dam layer DML1 formed in the same layer as the second planarization layer 126, the second dam layer DML2 formed in the same layer as the pixel defining layer 132, and the third dam layer DML3 formed in the same layer as the spacer layer 132′.

The encapsulation layer 140 of the display device 100 according to embodiments may include the first encapsulation layer 141 disposed on the element layer 130, the second encapsulation layer 142 disposed on the first encapsulation layer 141 and overlapping the display area DA, and the third encapsulation layer 143 disposed on the first encapsulation layer 141 and covering the second encapsulation layer 142.

The second encapsulation layer 142 may include an organic insulating material that extends to the one or more hole peripheral dams HPDM and is spaced apart from the hole area HLA.

Each of the first encapsulation layer 141 and the third encapsulation layer 143 may include an inorganic insulating material.

Since the second encapsulation layer 142 extends to the one or more hole peripheral dams HPDM, the first encapsulation layer 141 and the third encapsulation layer 143 may be in contact with each other in an area that is located between the hole area HLA and the one or more hole peripheral dams HPDM in the hole peripheral area PHA.

Further, the second encapsulation layer 142 may extend to the one or more hole peripheral dams HPDM, and the two or more encapsulation auxiliary portions ENAS may be arranged between the display area DA and the one or more hole peripheral dams HPDM in the hole peripheral area PHA. Therefore, the two or more encapsulation auxiliary portions ENAS may overlap the second encapsulation layer 142.

In this way, the two or more encapsulation auxiliary portions ENAS may be protected from physical impact by the second encapsulation layer 142.

As described above, in accordance with embodiments, the second common layer 136 and the cathode electrode 134 of the element layer 130 may be entirely disposed in the display area DA.

Accordingly, as shown in FIG. 8, the second common layer 136 and the cathode electrode 134 may also be disposed in the hole peripheral area PHA surrounded by the display area DA.

Since the second common layer 136 includes an organic material that is relatively susceptible to permeation of oxygen or moisture, oxygen or moisture may easily enter the circuit layer 120 and the element layer 130 of the display area DA through the second common layer 136 and the light transmitting hole TRH of the hole area HLA.

To prevent or delay this, as shown in FIG. 7, the circuit layer 120 of the display device 100 according to embodiments may include the two or more encapsulation auxiliary portions ENAS.

The two or more encapsulation auxiliary portions ENAS may sequentially surround the hole area HLA. In other words, the two or more encapsulation auxiliary portions ENAS may be sequentially arranged around the hole area HLA.

As shown in FIG. 8, in the third direction DR3 from the substrate 110 to the interlayer insulating layer 124, the cross section of each of the two or more encapsulation auxiliary portions ENAS may have a shape whose width gradually decreases as it approaches the interlayer insulating layer 124. In other words, the side surface of each of the two or more encapsulation auxiliary portions ENAS may have a reverse tapered cross section.

Accordingly, the second common layer 136 disposed in the hole peripheral area PHA may be separated by the reverse tapered side surface of each of the two or more encapsulation auxiliary portions ENAS. In other words, the second common layer 136 disposed in the hole peripheral area PHA may be divided into several parts without requiring an additional etching process or mask process for the second common layer 136. This separation of the second common layer 136 in the hole peripheral area PHA helps delay the permeation of oxygen or moisture through the second common layer 136.

Therefore, even if the display device 100 according to embodiments includes the light transmitting hole TRH surrounded by the display area DA, a drastic decrease in the lifespan may be prevented by the two or more encapsulation auxiliary portions ENAS.

In accordance with embodiments, each of the two or more encapsulation auxiliary portions ENAS may include a first auxiliary layer ASL1 disposed on the interlayer insulating layer 124 and spaced apart from the first planarization layer 125 of the display area DA, and a second auxiliary layer ASL2 disposed on the first auxiliary layer ASL1 and formed in the same layer as the second source-drain conductive layer SDCDL2. The first auxiliary layer ASL1 disposed on the interlayer insulating layer 124 may be in direct contact with the interlayer insulating layer 124.

In accordance with embodiments, the first auxiliary layer ASL1 may include a negative photoresist material cured by exposure.

Accordingly, when an exposure process is performed on a soft negative photoresist material laminated on the interlayer insulating layer 124 in a direction from the interlayer insulating layer 124 toward the substrate 110, a portion of the negative photoresist material closer to the interlayer insulating layer 124 may be exposed to a relatively smaller amount of light.

In other words, in the negative photoresist material exposed during the exposure process, the upper material, which is spaced further from the interlayer insulating layer 124, is exposed to a larger amount of light and therefore may have a relatively larger width. Conversely, the lower material, which is adjacent to the interlayer insulating layer 124, is exposed to a smaller amount of light, causing it to cohere together and therefore have a relatively smaller width.

For example, the first auxiliary layer ASL1 may have a thickness of about 1.5 μm to about 2.0 μm, enabling it to have a reverse tapered cross section due to the exposure difference.

In this way, since the first auxiliary layer ASL1 is made of a negative photoresist material, it may have a reverse tapered cross-sectional shape that gradually increases in width as it becomes more distant from the interlayer insulating layer 124 in the third direction DR3.

Since the first auxiliary layer ASL1 has a reverse tapered cross-sectional shape, the second auxiliary layer ASL2 may cover the top surface of the first auxiliary layer ASL1 and extend to a part of the side surface of the first auxiliary layer ASL1. That is, the second auxiliary layer ASL2 may be disposed only on a part of the side surface of the first auxiliary layer ASL1 that is connected to the top surface. In other words, the second auxiliary layer ASL2 does not extend to the interlayer insulating layer 124 along the side surface of the first auxiliary layer ASL1.

As described above, in accordance with embodiments, each of the two or more encapsulation auxiliary portions ENAS includes the first auxiliary layer ASL1 made of a negative photoresist material, and thus may relatively easily have a cross-sectional shape whose width gradually decreases as it approaches the interlayer insulating layer 124.

Further, since a separate mask process is not required for disposing the two or more encapsulation auxiliary portions ENAS, the display device 100 may be manufactured more simply.

Since the side surface of each of the two or more encapsulation auxiliary portions ENAS has a reverse tapered cross section, it is difficult for the second common layer 136 disposed in the hole peripheral area PHA to extend along the side surface of each of the two or more encapsulation auxiliary portions ENAS and reach the interlayer insulating layer 124. In other words, the second common layer 136 disposed in the hole peripheral area PHA may be separated by the two or more encapsulation auxiliary portions ENAS.

Accordingly, the second common layer 136 disposed in the hole peripheral area PHA may include two or more first split portions 1361, which are disposed on the second auxiliary layer ASL2 of each of the two or more encapsulation auxiliary portions ENAS, and one or more second split portions 1362, which are disposed on the interlayer insulating layer 124 between the two or more encapsulation auxiliary portions ENAS and spaced apart from the two or more first split portions 1361.

Since the two or more encapsulation auxiliary portions ENAS are spaced apart from the first planarization layer 125 of the display area DA, the two or more first split portions 1361 may be separated from the second common layer 136 of the display area DA.

In addition, in accordance with embodiments, the circuit layer 120 may include the one or more concave portions CCV disposed between the two or more encapsulation auxiliary portions ENAS and engraved on the interlayer insulating layer 124.

Accordingly, the one or more second split portions 1362 of the second common layer 136 disposed in the hole peripheral area PHA may be disposed in the one or more concave portions CCV.

In this way, the separation distance between the two or more first split portions 1361 and the one or more second split portions 1362 may be further increased by the one or more concave portions CCV engraved on the interlayer insulating layer 124, thereby further delaying the permeation of oxygen or moisture through the second common layer 136.

Additionally, in accordance with embodiments, the circuit layer 120 may further include the two or more dummy auxiliary portions DMAS disposed between the one or more hole peripheral dams HPDM and the hole area HLA and sequentially surrounding the hole area HLA. Additionally, one or more dummy concave portions DMCCV may be disposed between the two or more dummy auxiliary portions DMAS.

The two or more dummy auxiliary portions DMAS and the one or more dummy concave portions DMCCV are the same as the two or more encapsulation auxiliary portions ENAS and the one or more concave portions CCV except that they are disposed between the one or more hole peripheral dams HPDM and the hole area HLA and do not overlap with the second encapsulation layer 142. Therefore, redundant description will be omitted below.

In other words, each of the two or more dummy auxiliary portions DMAS may include a first dummy auxiliary layer DASL1 disposed on the interlayer insulating layer 124. The two or more dummy auxiliary portions DMAS include a negative photoresist material and each has a side surface with a reverse tapered cross-section. Additionally, a second dummy auxiliary layer DASL2 is disposed on the top surface and a part of the side surface of the first dummy auxiliary layer DASL1. The second dummy auxiliary layer DASL2 is formed in the same layer as the second source-drain conductive layer SDCDL2.

The second source-drain conductive layer SDCDL2 may include the normal data line NDL disposed in the display area DA, the hole bypass line HDE disposed in the hole peripheral area PHA, the second auxiliary layer ASL2, and the second dummy auxiliary layer DASL2.

The one or more dummy concave portions DMCCV may be engraved on the interlayer insulating layer 124.

Accordingly, the second common layer 136 disposed in the hole peripheral area PHA may further include two or more third split portions 1363 disposed on the two or more dummy auxiliary portions DMAS, and one or more fourth split portions 1364 disposed in the one or more dummy concave portions DMCCV and spaced apart from the two or more third split portions 1363.

The circuit layer 120 may further include the buffer layer 121 disposed on the substrate 110, the first gate insulating layer 122 disposed on the buffer layer 121, and the second gate insulating layer 123 disposed on the first gate insulating layer 122. The interlayer insulating layer 124 may be disposed on the second gate insulating layer 123.

Each of the buffer layer 121, the first gate insulating layer 122, the second gate insulating layer 123, and the interlayer insulating layer 124 may include an inorganic insulating material.

Each of the second common layer 136 and the cathode electrode 134 may be entirely disposed in the display area DA.

Each of the first encapsulation layer 141 and the third encapsulation layer 143 may include an inorganic insulating material and may be entirely disposed in the display area DA.

Accordingly, the light transmitting hole TRH of the hole area HLA may penetrate the third encapsulation layer 143, the first encapsulation layer 141, the cathode electrode 134, the second common layer 136, the interlayer insulating layer 124, the second gate insulating layer 123, the first gate insulating layer 122, the buffer layer 121, and the substrate 110.

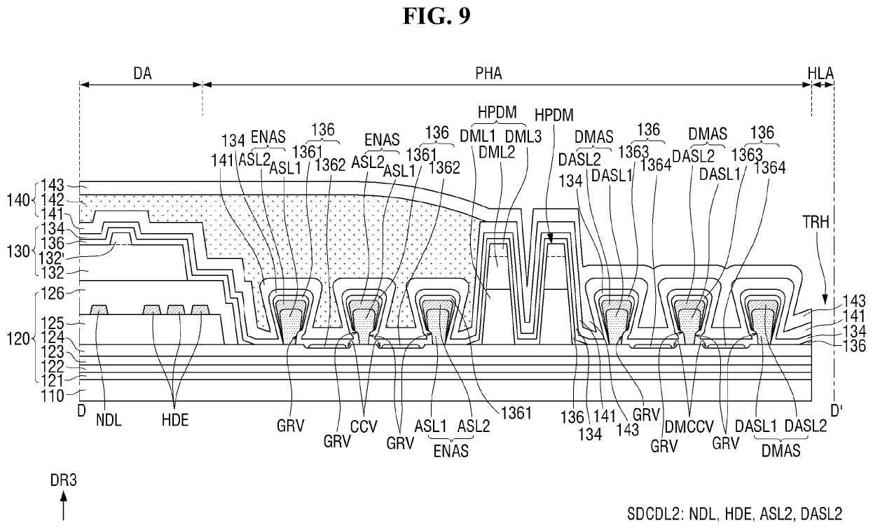

Referring to FIG. 9, the display device 100 according to an embodiment is substantially the same as the embodiments of FIG. 8 except that each of the two or more encapsulation auxiliary portions ENAS further includes one or more grooves GRV. Therefore, redundant description will be omitted below.

In each of the two or more encapsulation auxiliary portions ENAS, the one or more grooves GRV may be disposed on a side facing a neighboring encapsulation auxiliary portion ENAS and may be engraved on the side surface of the first auxiliary layer ASL1. The one or more grooves GRV may be engraved on a part of the side surface of the first auxiliary layer ASL1 where the second auxiliary layer ASL2 is not disposed. In other words, the second auxiliary layer ASL2 may not be located in the grooves GRV.

In this way, the side surface of each of the two or more encapsulation auxiliary portions ENAS may have steeper inclination due to the one or more grooves GRV. Accordingly, the two or more first split portions 1361 disposed on the two or more encapsulation auxiliary portions ENAS are relatively unlikely to extend into the groove GRV, and may extend only to the periphery of the groove GRV. Therefore, the separation distance between the two or more first split portions 1361 and the one or more second split portions 1362 may be secured to be greater than or equal to the width of the groove GRV.

Further, in accordance with the embodiment of FIG. 9, the two or more dummy auxiliary portions DMAS may also further include one or more grooves GRV.

Therefore, the permeation of oxygen or moisture by the second common layer 136 of the hole peripheral area PHA may be further delayed.

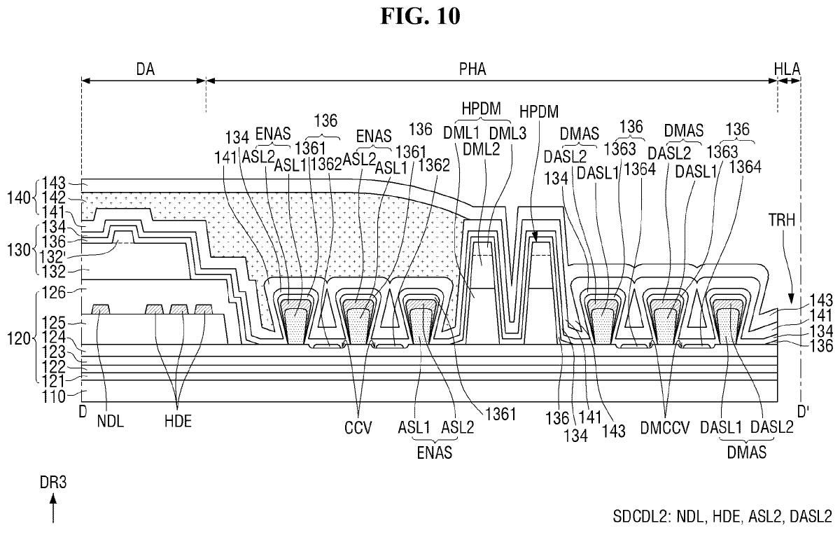

Referring to FIG. 10, the display device 100 according to another embodiment is substantially the same as the embodiments of FIG. 8 except that some portions of the first encapsulation layer 141 that overlap the two or more encapsulation auxiliary portions ENAS are connected to each other. Therefore, redundant description will be omitted below.

In accordance with another embodiment shown in FIG. 10, when the gap between the two or more encapsulation auxiliary portions ENAS is smaller than in the embodiments of FIG. 8, some portions of the first encapsulation layer 141 that overlap the two or more encapsulation auxiliary portions ENAS may be in contact with each other.

For example, in the embodiment shown in FIG. 10, the gap between the two or more encapsulation auxiliary portions ENAS may be greater than the sum of the thickness of the first split portions 1361 of the second common layer 136 and the thickness of the cathode electrode 134, but smaller than the sum of the thicknesses of the first split portions 1361 of the second common layer 136, the thickness of the cathode electrode 134, and the thickness of the first encapsulation layer 141.

In this way, an empty space surrounded by the first encapsulation layer 141 may be created in the region between the two or more encapsulation auxiliary portions ENAS. The second encapsulation layer 142 may not enter the empty space surrounded by the first encapsulation layer 141.

Accordingly, another part of the first encapsulation layer 141 that overlaps the one or more concave portions CCV may be spaced apart from the second encapsulation layer 142.

Therefore, the permeation of oxygen or moisture through the second common layer 136 and the second encapsulation layer 142 may be delayed.

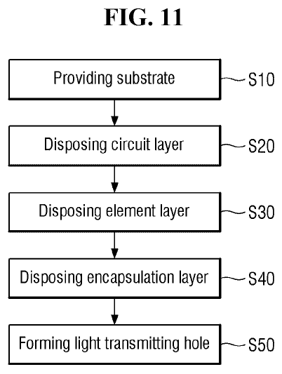

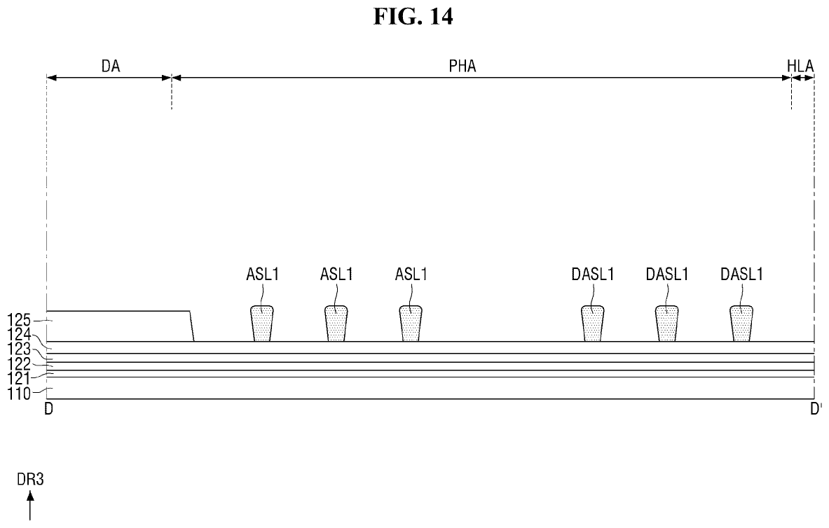

FIGS. 11, 12, and 13 are flowcharts illustrating a method for manufacturing the display device according to embodiments. FIGS. 14, 15, 16, 17, 18, 19, 20, 21, 22, 23 and 24 are process views showing some steps among the steps of FIGS. 11, 12 and 13.

Referring to FIG. 11, the method for manufacturing the display device 100 according to embodiments may include providing the substrate 110 (step S10), disposing the circuit layer 120 on the substrate 110 (step S20), disposing the element layer 130 on the circuit layer 120 (step S30), disposing the encapsulation layer 140 on the element layer 130 (step S40), and forming the light transmitting hole TRH penetrating the substrate 110, the circuit layer 120, the element layer 130, and the encapsulation layer 140 in the hole area HLA (see FIG. 2) (step S50).

In step S10 of providing the substrate 110, the substrate 110 may include the display area DA (see FIG. 2) where the emission areas EA (see FIG. 4) are arranged, the non-display area NDA (see FIG. 2) disposed around the display area DA, the hole area HLA (see FIG. 2) surrounded by the display area DA, and the hole peripheral area PHA (see FIG. 2) disposed between the display area DA and the hole area HLA.

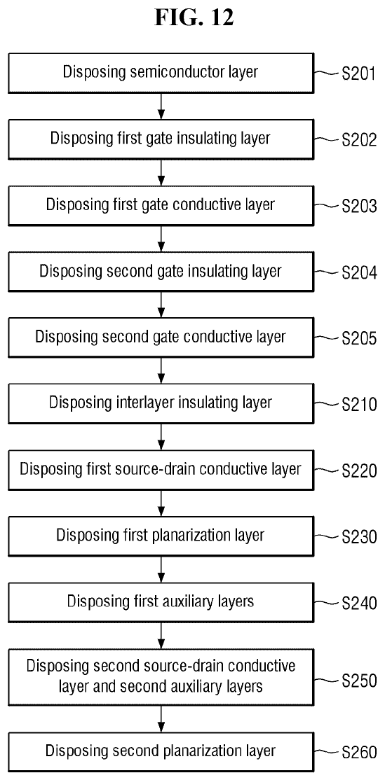

Referring to FIG. 12, step S20 of disposing the circuit layer 120 according to embodiments may include disposing the interlayer insulating layer 124 (see FIG. 8) on the substrate 110 (step S210), disposing the first source-drain conductive layer SDCDL1 (see FIG. 6) in the display area DA on the interlayer insulating layer 124 (step S220), disposing the first planarization layer 125 covering the first source-drain conductive layer SDCDL1 in the display area DA on the interlayer insulating layer 124 (step S230), disposing the two or more first auxiliary layers ASL1 (see FIG. 8) in the hole peripheral area PHA on the interlayer insulating layer 124 (step S240), disposing the second source-drain conductive layer SDCDL2 (see FIG. 6) on the first planarization layer 125 and disposing the two or more second auxiliary layers ASL2 on the two or more first auxiliary layers ASL1 (step S250), and disposing the second planarization layer 126 covering the second source-drain conductive layer SDCDL2 on the first planarization layer 125 (step S260).

Step S20 of disposing the circuit layer 120 according to embodiments may include, before step S210 of disposing the interlayer insulating layer 124, disposing the semiconductor layer CH1, E11, E21, CH6, E16, and E26 (see FIG. 6) on the substrate 110 (step S201), disposing the first gate insulating layer 122 (see FIGS. 6 and 8) covering the semiconductor layer (step S202), disposing the first gate conductive layer G1 and G6 (see FIG. 6) on the first gate insulating layer 122 (step S203), disposing the second gate insulating layer 123 (see FIGS. 6 and 8) covering the first gate conductive layer (step S204), and disposing the second gate conductive layer CAE (see FIG. 6) on the second gate insulating layer 123 (step S205).

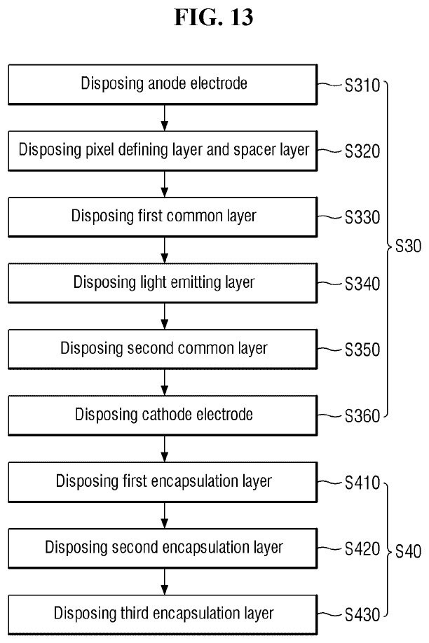

Referring to FIG. 13, step S30 of disposing the element layer 130 according to embodiments may include disposing the anode electrodes 131 (see FIG. 6) of the emission areas EA on the second planarization layer 126 (step S310), disposing the pixel defining layer 132 (see FIGS. 6 and 8) in the non-emission area disposed between the emission areas EA on the second planarization layer 126, and disposing the spacer layer 132′ (see FIGS. 6 and 8) on a part of the pixel defining layer 132 (step S320), disposing the first common layers 135 (see FIG. 6) on the anode electrodes 131 (step S330), disposing the light emitting layers 133 (see FIG. 6) on the first common layers 135 (step S340), disposing the second common layer 136 (see FIGS. 6 and 8) to cover the pixel defining layer 132, the spacer layer 132′, and the light emitting layers 133 in the display area DA (step S350), and disposing the cathode electrode 134 (see FIGS. 6 and 8) on the second common layer 136 (step S360).

Step S40 of disposing the encapsulation layer 140 may include disposing the first encapsulation layer 141 (see FIG. 8) (step S410), disposing the second encapsulation layer 142 (see FIG. 8) (step S420), and disposing the third encapsulation layer 143 (see FIG. 8) (step S430).

Referring to FIG. 14, in step S240, two or more first auxiliary layers ASL1 may be disposed in the hole peripheral area PHA on the interlayer insulating layer 124 by partially etching the negative photoresist material laminated on the interlayer insulating layer 124.

The two or more first auxiliary layers ASL1 may be formed by a part of the negative photoresist material that is exposed in the exposure process on the interlayer insulating layer 124.

The two or more first auxiliary layers ASL1 may sequentially surround the hole area HLA and may be spaced apart from the first planarization layer 125.

In the third direction DR3, the cross section of each of the two or more first auxiliary layers ASL1 may have a shape whose width gradually decreases as it approaches the interlayer insulating layer 124.

In step S240, two or more first dummy auxiliary layers DASL1 that are more adjacent to the hole area HLA than the two or more first auxiliary layers ASL1 may be further disposed.

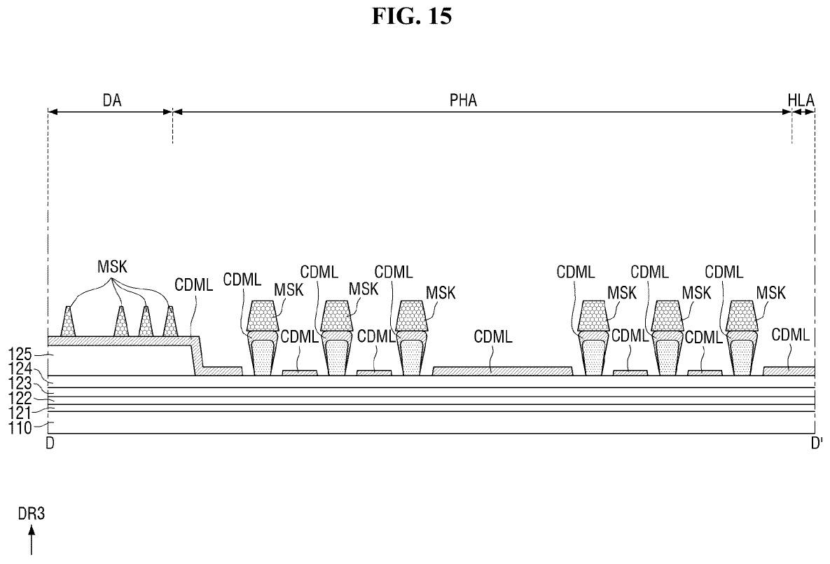

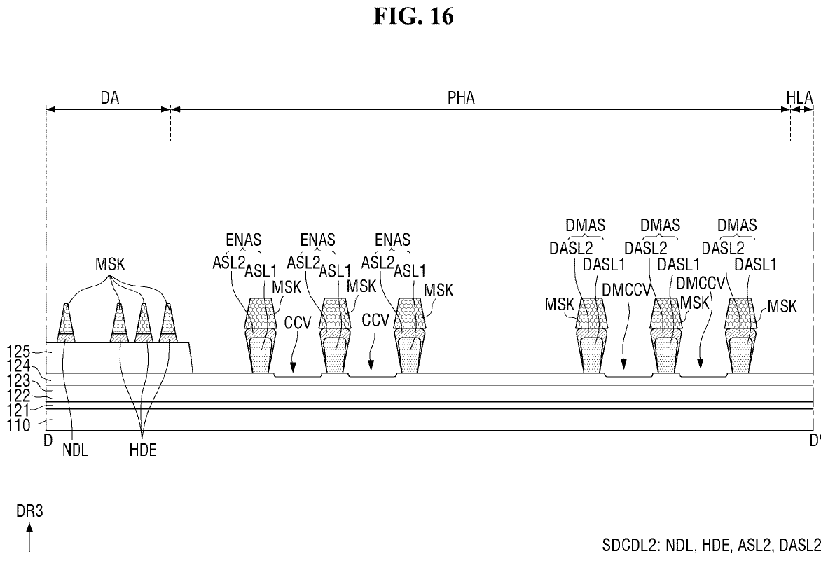

Referring to FIGS. 15 and 16, step S250 may include disposing a conductive material layer CDML covering the first planarization layer 125, the two or more first auxiliary layers ASL1, and the two or more first dummy auxiliary layers DASL1, and partially removing the conductive material layer CDML using a mask layer MSK on the conductive material layer CDML.

As shown in FIG. 15, some portions of the conductive material layer CDML, laminated in the gap between the two or more first auxiliary layers ASL1 and the two or more first dummy auxiliary layers DASL1, may be disposed to have a relatively small thickness.

As shown in FIG. 16, in the step of partially removing the conductive material layer CDML, the second source-drain conductive layer SDCDL2 may be formed form portions of the conductive material layer CDML that remain after being masked by the mask layer MSK on the first planarization layer 125.

In the step of partially removing the conductive material layer CDML, the two or more second auxiliary layers ASL2 may be provided by the conductive material layer CDML on the two or more first auxiliary layers ASL1. Accordingly, the two or more encapsulation auxiliary portions ENAS, each including a laminated structure of the first auxiliary layer ASL1 and the second auxiliary layer ASL2, may be provided.

Further, in the step of partially removing the conductive material layer CDML, the two or more second dummy auxiliary layers DASL2 may be provided by the conductive material layer CDML on the two or more first dummy auxiliary layers DASL1. Therefore, the two or more dummy auxiliary portions DMAS, each including a laminated structure of the first dummy auxiliary layer DASL1 and the second dummy auxiliary layer DASL2, may be provided.

In addition, since the conductive material layer CDML is disposed with a relatively small thickness between the two or more first auxiliary layers ASL1 and between the two or more first dummy auxiliary layers DASL1, in the step of partially removing the conductive material layer CDML, the interlayer insulating layer 124 may be exposed to an etching process after the conductive material layer CDML is removed.

In other words, between the two or more first auxiliary layers ASL1, a part of the interlayer insulating layer 124 may be removed together with the conductive material layer CDML. Accordingly, one or more concave portions CCV may be formed on the interlayer insulating layer 124 between the two or more first auxiliary layers ASL1.

Further, the one or more dummy concave portions DMCCV may be formed between the two or more first dummy auxiliary layers DASL1.

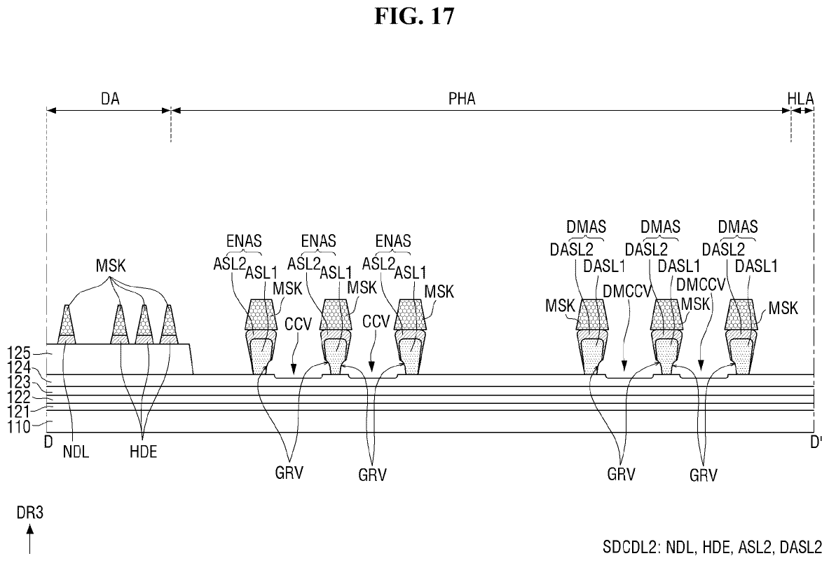

As shown in FIG. 17, the method for manufacturing the display device 100 according to the embodiment of FIG. 9 may further include, after step S250, performing an ashing process on the side surfaces of the two or more first auxiliary layers ASL1.

Accordingly, the one or more grooves GRV may be formed on the side surface of each of the two or more first auxiliary layers ASL1.

Further, the one or more grooves GRV may also be formed on the side surface of each of the two or more first dummy auxiliary layers DASL1.

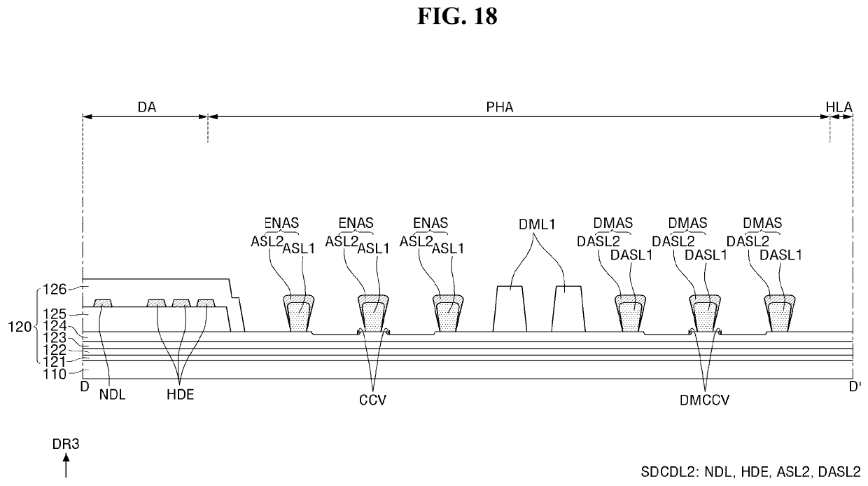

Subsequent to the process of FIG. 16 or 17, as shown in FIG. 18, in step S260, the second planarization layer 126 may be disposed in the display area DA by partially removing the organic insulating material covering the second source-drain conductive layer SDCDL2 and the two or more second auxiliary layers ASL2.

In addition, the first dam layer DML1 of the one or more hole peripheral dams HPDM may be disposed between the two or more encapsulation auxiliary portions ENAS and the two or more dummy auxiliary portions DMAS.

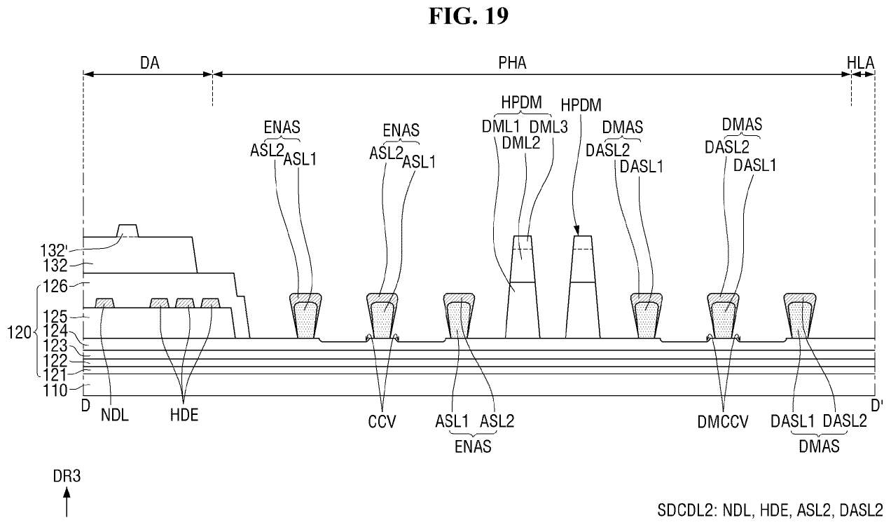

As shown in FIG. 19, in step S320, by partially removing the organic insulating material covering the anode electrodes 131, the two or more encapsulation auxiliary portions ENAS, the two or more dummy auxiliary portions DMAS, and the first dam layer DML1, the pixel defining layer 132 of the non-emission area may be provided by a part of the organic insulating material that has a first thickness, and the spacer layer 132′ may be provided by another part of the organic insulating layer that is maintained at a second thickness greater than the first thickness.

Further, the second dam layer DML2 and the third dam layer DML3 may be formed form another portion of the organic insulating material on the first dam layer DML1. Accordingly, the one or more hole peripheral dams HPDM may be provided in the hole peripheral area PHA.

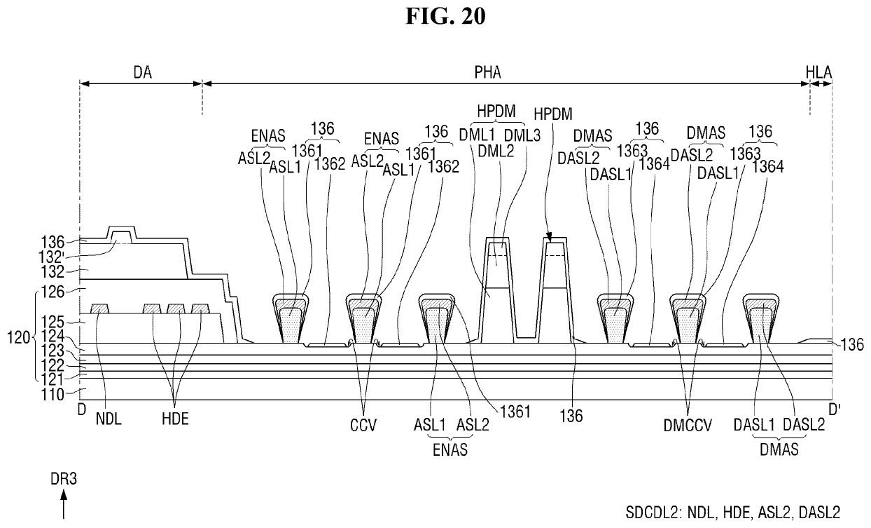

Referring to FIG. 20, in step S350, the second common layer 136 may be disposed by entirely laminating an organic material in the display area DA and the hole peripheral area PHA and the hole area HLA that are surrounded by the display area DA.

The second common layer 136 disposed in the hole peripheral area PHA may include the two or more first split portions 1361 disposed on the two or more encapsulation auxiliary portions ENAS, and the one or more second split portions 1362 disposed on the one or more concave portions CCV and spaced apart from the two or more first split portions 1361.

The two or more first split portions 1361 may be spaced apart from each other, and may also be spaced apart from a part of the second common layer 136 that is disposed in the display area DA.

The second common layer 136 disposed in the hole peripheral area PHA may further include the two or more third split portions 1363 disposed on the two or more dummy auxiliary portions DMAS, and the one or more fourth split portions 1364 disposed on the one or more dummy concave portions DMCCV and spaced apart from the two or more third split portions 1363.

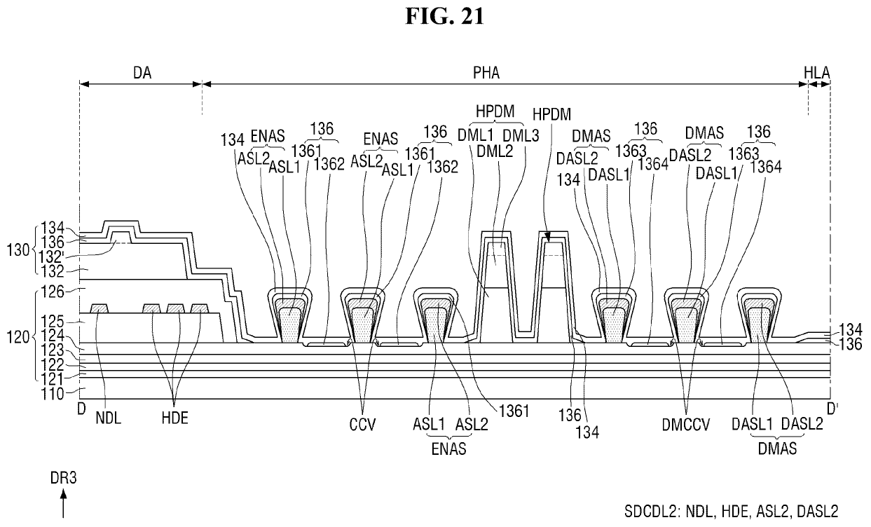

Referring to FIG. 21, in step S360, the cathode electrode 134 may be provided by laminating a light transmitting conductive material covering the second common layer 136 in the display area DA and the hole peripheral area PHA and the hole area HLA that are surrounded by the display area DA.

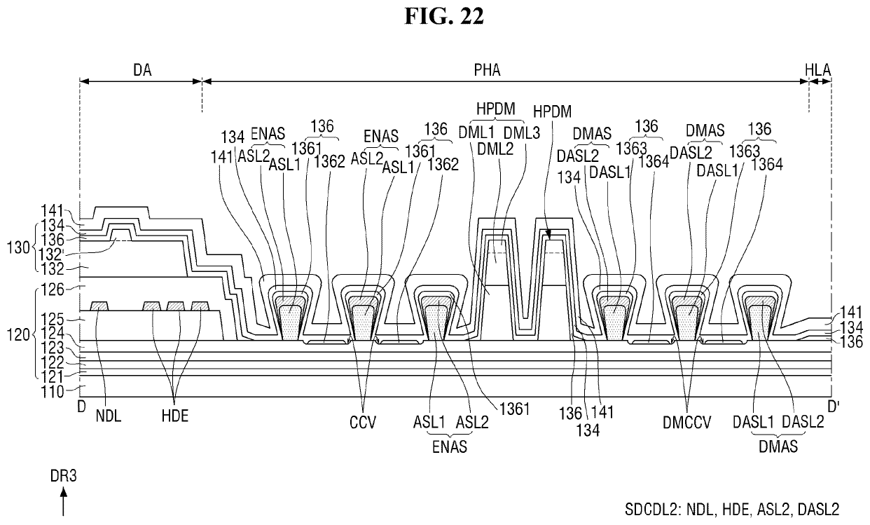

Referring to FIG. 22, in step S410, the first encapsulation layer 141 may be provided by laminating an inorganic insulating material covering the cathode electrode 134 in the display area DA and the hole peripheral area PHA and the hole area HLA that are surrounded by the display area DA.

In accordance with the embodiment shown in FIG. 10, in step S410, some of the first encapsulation layer 141 that overlaps the two or more second auxiliary layers ASL2 may be connected to each other. In other words, parts of the first encapsulation layer 141 that are overlapping the two or more second auxiliary layers ASL2 could be in direct physical or electrical contact with one another.

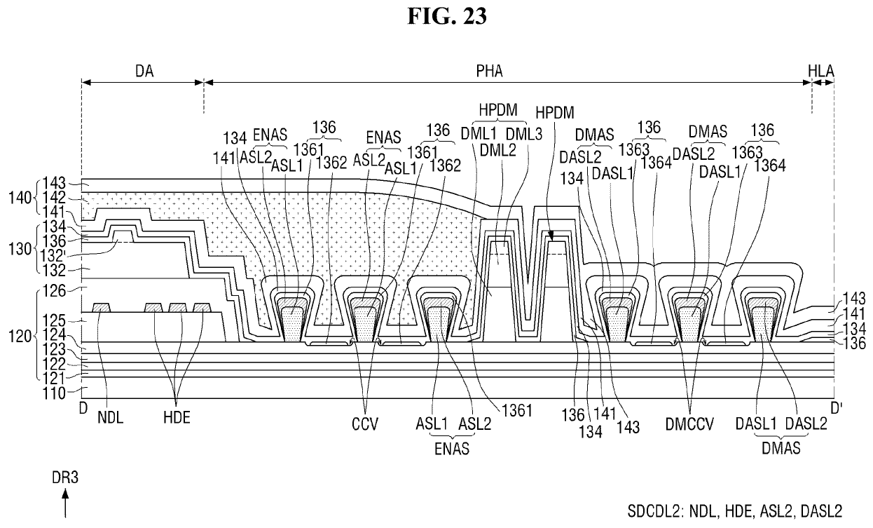

Subsequent to the process of FIG. 22, as shown in FIG. 23, in step S420, the second encapsulation layer 142 may be provided by diffusing a liquid organic insulating material dropped on the display area DA to the one or more hole peripheral dams HPDM and then curing it.

Then, in step S430, the third encapsulation layer 143 may be provided by laminating an inorganic insulating layer covering the second encapsulation layer 142 in the display area DA and the hole peripheral area PHA and the hole area HLA that are surrounded by the display area DA.

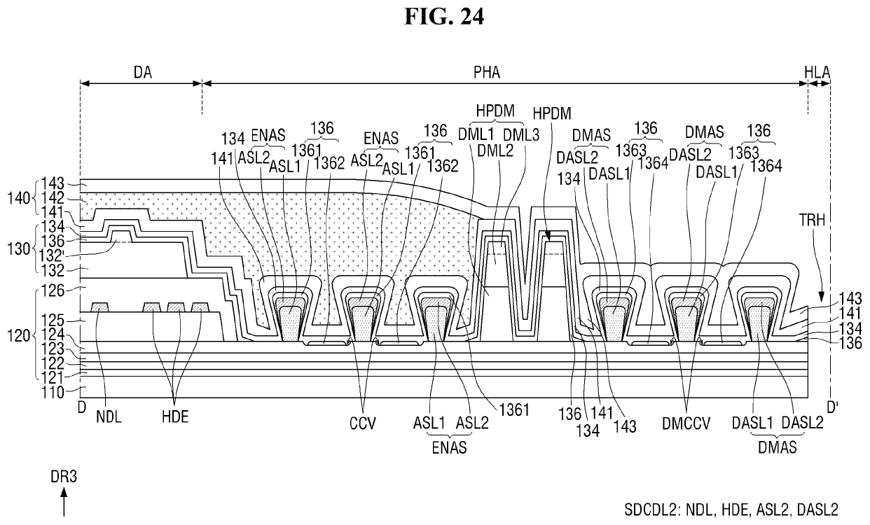

Then, as shown in FIG. 24, in step S50, the light transmitting hole TRH penetrating the third encapsulation layer 143, the first encapsulation layer 141, the cathode electrode 134, the second common layer 136, the interlayer insulating layer 124, the second gate insulating layer 123, the first gate insulating layer 122, the buffer layer 121, and the substrate 110 may be formed by performing chemical or mechanical etching in the hole area HLA.

However, the effects of the present disclosure are not limited to those set forth herein. Additional effects will become more apparent to those skilled in the art by referencing the claims.

What is claimed is:

1. A display device comprising:
a substrate;
a circuit layer disposed on the substrate;
an element layer disposed on the circuit layer; and
an encapsulation layer disposed on the element layer,
wherein the substrate comprises:
a display area in which emission areas are arranged;
a non-display area adjacent to the display area;
a hole area surrounded by the display area; and
a hole peripheral area disposed between the hole area and the display area, and the circuit layer comprises:
an interlayer insulating layer disposed on the substrate;
two or more encapsulation auxiliary portions disposed in the hole peripheral area on the interlayer insulating layer, wherein the two or more encapsulation auxiliary portions surround the hole area; and
one or more concave portions disposed between the two or more encapsulation auxiliary portions, wherein the one or more concave portions are located on the interlayer insulating layer,
wherein in a direction from the substrate to the interlayer insulating layer, each of the two or more encapsulation auxiliary portions has a cross-sectional shape whose width gradually narrows as it approaches the interlayer insulating layer.

2. The display device of claim 1, further comprising a light transmitting hole in the hole area, wherein the light transmitting hole penetrates the substrate, the circuit layer, the element layer, and the encapsulation layer.

3. The display device of claim 2, further comprising one or more hole peripheral dams disposed between the two or more encapsulation auxiliary portions and the hole area, wherein the one or more hole peripheral dams surround the hole area,
wherein the encapsulation layer comprises:
a first encapsulation layer disposed on the element layer;
a second encapsulation layer disposed on the first encapsulation layer and overlapping the display area; and
a third encapsulation layer disposed on the first encapsulation layer and the second encapsulation layer,
wherein the second encapsulation layer includes an organic insulating material that extends to the one or more hole peripheral dams and is spaced from the hole area;
the first encapsulation layer and the third encapsulation layer include an inorganic insulating material, and are in contact with each other in a region between the hole area and the one or more hole peripheral dams, and
the two or more encapsulation auxiliary portions overlap the second encapsulation layer.

4. The display device of claim 3, wherein the circuit layer further comprises:
a first source-drain conductive layer disposed on the interlayer insulating layer;
a first planarization layer disposed in the display area on the interlayer insulating layer, wherein the first planarization layer is spaced apart from the two or more encapsulation auxiliary portions, and covers the first source-drain conductive layer;
a second source-drain conductive layer disposed on the first planarization layer; and
a second planarization layer disposed on the first planarization layer, wherein the second planarization layer covers the second source-drain conductive layer, and
each of the two or more encapsulation auxiliary portions comprises:
a first auxiliary layer disposed on the interlayer insulating layer and spaced apart from the first planarization layer; and
a second auxiliary layer disposed on the first auxiliary layer and formed in the same layer as the second source-drain conductive layer,
wherein the second auxiliary layer covers a top surface of the first auxiliary layer, extends to a side surface of the first auxiliary layer, and is spaced apart from the interlayer insulating layer.

5. The display device of claim 4, wherein the first auxiliary layer includes a negative photoresist material that is cured by exposure, and has a cross-sectional shape that gradually widens as it extends away from the interlayer insulating layer in the direction from the substrate to the interlayer insulating layer.

6. The display device of claim 4, wherein each of the two or more encapsulation auxiliary portions is disposed on a side facing an adjacent encapsulation auxiliary portion, and further comprises one or more grooves formed on a side surface of the first auxiliary layer.

7. The display device of claim 4, wherein the first encapsulation layer overlapping the two or more encapsulation auxiliary portions is contiguous, and
the first encapsulation layer overlapping the one or more concave portions is spaced apart from the second encapsulation layer.

8. The display device of claim 4, wherein the element layer comprises:
anode electrodes disposed in the emission areas;
a pixel defining layer disposed in a non-emission area between the emission areas, wherein the pixel defining layer covers an edge of each of the anode electrodes;
a spacer layer disposed on the pixel defining layer;
first common layers disposed on the anode electrodes;
light emitting layers disposed on the first common layers;
a second common layer disposed in the display area, wherein the second common layer covers the pixel defining layer, the spacer layer, and the light emitting layers; and
a cathode electrode disposed on the second common layer.

9. The display device of claim 8, wherein the second common layer comprises:
two or more first split portions disposed on the second auxiliary layer of each of the two or more encapsulation auxiliary portions; and
one or more second split portions disposed in the one or more concave portions, wherein the one or more second split portions are spaced apart from the two or more first split portions.

10. The display device of claim 9, wherein between the two or more encapsulation auxiliary portions, the cathode electrode is in contact with the interlayer insulating layer.

11. The display device of claim 8, wherein in the circuit layer, each of the one or more hole peripheral dams comprises two or more dam layers, and
each of the two or more dam layers is disposed in the same layer as the second planarization layer, the pixel defining layer, or the spacer layer.

12. The display device of claim 8, further comprising:
two or more dummy auxiliary portions disposed between the one or more hole peripheral dams and the hole area, wherein the two or more dummy auxiliary portions surround the hole area; and
one or more dummy concave portions disposed between the two or more dummy auxiliary portions,
wherein the second common layer further comprises:
two or more third split portions disposed on the two or more dummy auxiliary portions; and
one or more fourth split portions disposed in the one or more dummy concave portions, wherein the one or more fourth split portions are spaced apart from the two or more third split portions.

13. The display device of claim 12, wherein the circuit layer further comprises:
a buffer layer disposed on the substrate;
a first gate insulating layer disposed on the buffer layer; and
a second gate insulating layer disposed on the first gate insulating layer,
wherein the interlayer insulating layer is disposed on the second gate insulating layer, and
the light transmitting hole penetrates the third encapsulation layer, the first encapsulation layer, the cathode electrode, the second common layer, the interlayer insulating layer, the second gate insulating layer, the first gate insulating layer, the buffer layer, and the substrate.

14. A method for manufacturing a display device, comprising:
providing a substrate comprising a display area in which emission areas are arranged; a non-display area disposed around the display area; a hole area surrounded by the display area; and a hole peripheral area disposed between the hole area and the display area;
disposing a circuit layer on the substrate;
disposing an element layer on the circuit layer;
disposing an encapsulation layer on the element layer; and
forming a light transmitting hole penetrating the substrate, the circuit layer, the element layer, and the encapsulation layer in the hole area,
wherein the disposing of the circuit layer comprises:
disposing an interlayer insulating layer on the substrate;
disposing a first source-drain conductive layer on the interlayer insulating layer;
disposing a first planarization layer covering the first source-drain conductive layer in the display area on the interlayer insulating layer;
disposing two or more first auxiliary layers surrounding the hole area in the hole peripheral area on the interlayer insulating layer by partially etching a negative photoresist material laminated on the interlayer insulating layer, wherein the two or more first auxiliary layers are spaced apart from the first planarization layer;
disposing a second source-drain conductive layer on the first planarization layer, and disposing two or more second auxiliary layers on the two or more first auxiliary layers; and
disposing a second planarization layer covering the second source-drain conductive layer on the first planarization layer.

15. The method of claim 14, wherein a cross section of each of the two or more first auxiliary layers has a shape whose width gradually decreases as it approaches the interlayer insulating layer, and
the disposing of the second source-drain conductive layer and the two or more second auxiliary layers comprises:
laminating a conductive material layer; and
partially removing the conductive material layer to provide the second source-drain conductive layer as a conductive material layer on the first planarization layer, and to provide the two or more second auxiliary layers as a conductive material layer on the two or more first auxiliary layers,
wherein the two or more second auxiliary layers cover top surfaces of the two or more first auxiliary layers, extend to a part of side surfaces of the two or more first auxiliary layers, and are spaced apart from the interlayer insulating layer, and
in the disposing of the second source-drain conductive layer and the two or more second auxiliary layers, two or more encapsulation auxiliary portions each having a laminated structure of the first auxiliary layer and the second auxiliary layer are formed.

16. The method of claim 15, wherein in the partially removing of the conductive material layer, between the two or more first auxiliary layers, a part of the interlayer insulating layer is removed together with the conductive material layer, and one or more concave portions are formed on the interlayer insulating layer.

17. The method of claim 16, wherein the disposing of the element layer comprises:
disposing anode electrodes of the emission areas on the second planarization layer;
disposing a pixel defining layer of a non-emission area disposed between the emission areas on the second planarization layer, and disposing a spacer layer on a part of the pixel defining layer;
disposing first common layers on the anode electrodes;
disposing light emitting layers on the first common layers;
disposing a second common layer covering the pixel defining layer, the spacer layer, and the light emitting layers in the display area; and
disposing a cathode electrode on the second common layer,
wherein the second common layer comprises:
two or more first split portions disposed on the two or more second auxiliary layers; and
one or more second split portions disposed in the one or more concave portions and spaced apart from the two or more first split portions.

18. The method of claim 17, wherein the disposing of the circuit layer further comprises:
after disposing the second source-drain conductive layer and the two or more second auxiliary layers, performing an ashing process on the side surfaces of the two or more first auxiliary layers to form one or more grooves in each of the two or more first auxiliary layers, and
the one or more grooves of each of the two or more first auxiliary layers are disposed on a side facing an adjacent first auxiliary layer, and are formed on a side surface of the first auxiliary layer.

19. The method of claim 17, wherein in the disposing of the pixel defining layer and the spacer layer, one or more hole peripheral dams disposed between the two or more encapsulation auxiliary portions and the hole area and surrounding the hole area are formed,
the one or more hole peripheral dams comprise two or more dam layers,
each of the two or more dam layers is formed in the same layer as one of the second planarization layer, the pixel defining layer, and the spacer layer, and
the disposing of the encapsulation layer comprises:
disposing a first encapsulation layer covering the cathode electrode and containing an inorganic insulating material;
disposing a second encapsulation layer overlapping the display area on the first encapsulation layer; and
laminating an inorganic insulating material on the first encapsulation layer and disposing a third encapsulation layer covering the second encapsulation layer,
wherein the second encapsulation layer includes an organic insulating material extending to the one or more hole peripheral dams, overlapping the two or more encapsulation auxiliary portions, and spaced away from the hole area.

20. The method of claim 19, wherein some of the first encapsulation layer overlapping the two or more second auxiliary layers are connected to each other.
